(19) United States
(12) Patent Application Publication
(10) Pub. No.: US 2026/0003272 A1
(43) Pub. Date: Jan. 1, 2026

(54) CURABLE COMPOSITION, CURED LAYER USING THE COMPOSITION, AND DISPLAY DEVICE INCLUDING THE CURED LAYER

(71) Applicant: SAMSUNG SDI CO., LTD., Yongin-si (KR)

(72) Inventors: Sohyun KIM, Suwon-si (KR); Yonghee KANG, Suwon-si (KR); Chul-Kyu KIM, Suwon-si (KR); Jihyeon YIM, Suwon-si (KR); Bumjin LEE, Suwon-si (KR)

(21) Appl. No.: 19/235,126

(22) Filed: Jun. 11, 2025

(30) Foreign Application Priority Data
Jun. 26, 2024 (KR) 10-2024-0083883

(51) Int. Cl. G03F 7/028; C09K 11/88; H10H 29/851

(52) U.S. Cl. CPC G03F 7/028; C09K 11/883; H10H 29/8512

(57) ABSTRACT

A curable composition, a cured layer produced using the curable composition, and a display device including the cured layer are provided. The curable composition includes: (A) a quantum dot including a first functional group represented by Chemical Formula 1 and a second functional group having a different structure from the first functional group; and (B) a polymerizable compound.

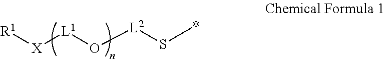

### CROSS-REFERENCE TO RELATED APPLICATION

The present application claims priority to and the benefit of Korean Patent Application No. 10-2024-0083883, filed in the Korean Intellectual Property Office on Jun. 26, 2024, the entire content of which is incorporated herein by reference.

### BACKGROUND

### 1. Field

One or more embodiments of the present disclosure relate to a curable composition, a cured layer using the composition, and a display device including the cured layer.

### 2. Description of the Related Art

Quantum dots have been used in display device. Due to their hydrophobic surface characteristics, the solvents in which the quantum dots are well dispersed are limited. Thus, it is difficult to introduce quantum dots into a polar system such as a binder and/or a curable monomer.

For example, quantum dot ink compositions have been actively researched. Because the polarity of quantum dots is relatively low initially, the quantum dots may be dispersed in a solvent with high hydrophobicity to prepare a curable composition. Even so, quantum dots with a concentration of 20 wt % or more, based on the total amount of the curable composition, are difficult to include. Due to this limiting concentration of the quantum dots, it is impossible or very difficult to increase the light efficiency of the ink beyond a certain level. Although the quantum dots can be additionally added and dispersed to increase light efficiency, the viscosity of the curable composition may exceed a range capable of ink-jetting, thus compromising processability.

To achieve the viscosity suitable for ink-jetting, a method of lowering the ink solid content by including about 50 wt % or more of a solvent, based on the total amount of the composition, is utilized. This provides a somewhat satisfactory result in terms of viscosity. However, nozzle drying due to solvent volatilization and nozzle clogging during ink-jetting may occur. As time passes after ink-jetting, reduction of single film thickness and difficulty in controlling thickness deviation after curing may worsen, making it difficult to apply this method to actual processes.

Accordingly, a solvent-free curable composition (quantum dot ink composition) that does not use a solvent has been researched and developed. However, due to an excessive amount of a polymerizable compound, issues, such as clogging and/or poor ejection due to nozzle drying caused by volatility, and a decrease in single film thickness due to volatilization of the jetted ink composition within the pattern partition wall pixel arise. Above all, the biggest issue is that it is difficult to improve the optical properties of the solvent-free curable composition.

For example, neither solvent-type (kind) curable composition nor solvent-free curable composition has yet demonstrated a satisfactory level of light resistance reliability.

### SUMMARY

One or more aspects of embodiments of the present disclosure are directed toward a curable composition having high stability of quantum dots, excellent or suitable dispersibility of quantum dots, and thus excellent or suitable reliability and optical properties such as heat resistance and light resistance.

One or more aspects of embodiments of the present disclosure are directed toward a cured layer produced using the curable composition.

One or more aspect of embodiments of the present disclosure are directed toward a display device including the cured layer.

Additional aspects will be set forth in part in the description which follows and, in part, will be apparent from the description, or may be learned by practice of the presented embodiments of the disclosure.

According to one or more embodiments of the present disclosure, a curable composition includes: (A) a quantum dot including a first functional group represented by Chemical Formula 1 and a second functional group having a different structure from the first functional group; and (B) a polymerizable compound.

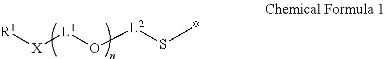

In Chemical Formula 1,
X is sulfur or oxygen,
R¹ is a monovalent functional group including a reactive group and a C3 to C20 cycloalkane ring,
L¹ and L² are each independently a substituted or unsubstituted C1 to C20 alkylene group, and
n is an integer between 2 and 10.

The reactive group may include a carbon-carbon double bond, an epoxy group, and/or a (e.g., any suitable) combination thereof.

In one or more embodiments, R¹ may be represented by any one selected from among Chemical Formulas R-1 to R-3.

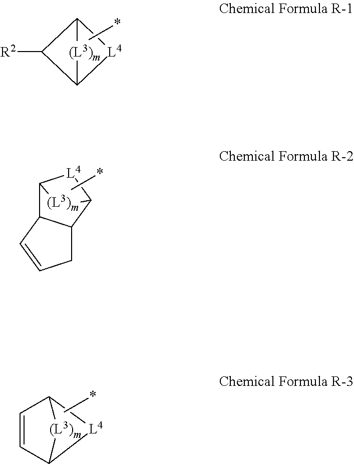

In Chemical Formulas R-1 to R-3,
R² is a substituted or unsubstituted vinyl group, a substituted or unsubstituted epoxy group, or a C1 to C20 alkyl group substituted with an epoxy group and/or a vinyl group,
L³ and L⁴ are each independently a substituted or unsubstituted C1 to C10 alkylene group, and
m is an integer of 0 or 1.

In one or more embodiments, the first functional group represented by Chemical Formula 1 may be represented by any one selected from among Chemical Formula 1-1 to Chemical Formula 1-4.

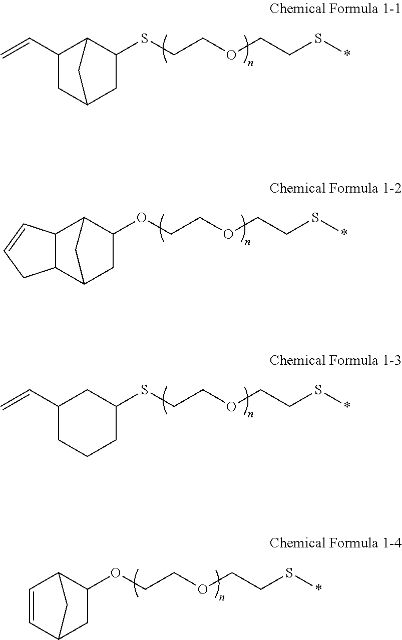

In Chemical Formula 1-1 to Chemical Formula 1-4,
n is an integer between 2 and 10.

In one or more embodiments, the first functional group represented by Chemical Formula 1 may be derived from a compound represented by Chemical Formula 11.

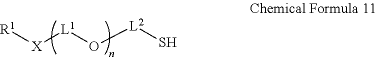

In Chemical Formula 11,
X is sulfur or oxygen,
R¹ is a monovalent functional group including a reactive group and a C3 to C20 cycloalkane ring,
L¹ and L² are each independently a substituted or unsubstituted C1 to C20 alkylene group, and
n is an integer between 2 and 10.

In one or more embodiments, in Chemical Formula 11, the definitions of the reactive groups, X, R¹, L¹, L², and n are the same as described in Chemical Formula 1.

In one or more embodiments, the compound represented by Chemical Formula 11 may be represented by any one selected from among Chemical Formula 11-1 to Chemical Formula 11-4.

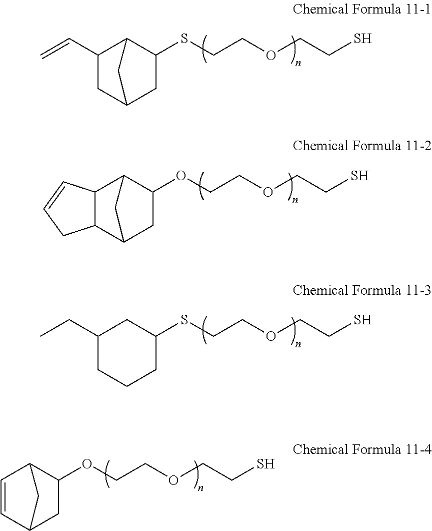

In Chemical Formula 11-1 to Chemical Formula 11-4,
n is an integer between 2 and 10.

The second functional group may be represented by Chemical Formula 2 or Chemical Formula 3.

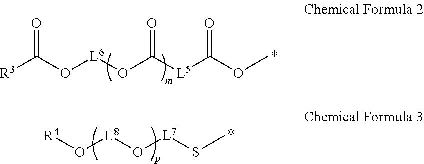

In Chemical Formula 2 and Chemical Formula 3,
R³ and R⁴ are each independently a substituted or unsubstituted vinyl group, a substituted or unsubstituted epoxy group, or a C1 to C20 alkyl group substituted with an epoxy group and/or a vinyl group,
L⁵ to L⁸ are each independently a substituted or unsubstituted C1 to C20 alkylene group, and
m and p are each independently an integer from 0 to 10.

In one or more embodiments, the second functional group represented by Chemical Formula 2 may be represented by either Chemical Formula 2-1 or Chemical Formula 2-2.

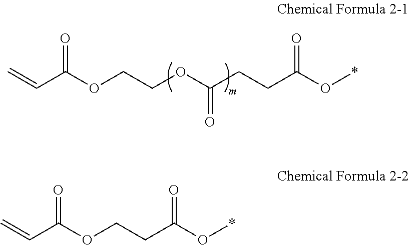

In Chemical Formula 2-1,
m is an integer from 1 to 10.

In one or more embodiments, the second functional group represented by Chemical Formula 3 may be represented by Chemical Formula 3-1.

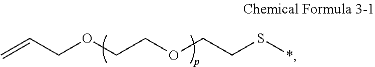

In Chemical Formula 3-1,
p is an integer from 0 to 10.

In one or more embodiments, the second functional group may be derived from a compound represented by Chemical Formula 12 or Chemical Formula 13.

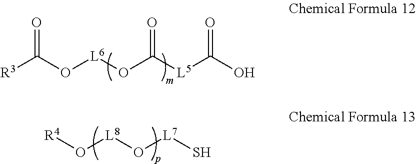

In Chemical Formula 12 and Chemical Formula 13,
R³ and R⁴ may each independently be a substituted or unsubstituted vinyl group, a substituted or unsubstituted epoxy group, or a C1 to C20 alkyl group substituted with an epoxy group and/or a vinyl group,
L⁵ to L⁸ may each independently be a substituted or unsubstituted C1 to C20 alkylene group, and
m and p may each independently be an integer from 0 to 10.

In one or more embodiments, the compound represented by Chemical Formula 12 may be represented by either Chemical Formula 12-1 or Chemical Formula 12-2.

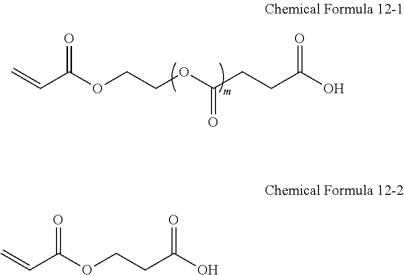

In Chemical Formula 12-1,
m is an integer from 1 to 10.

In one or more embodiments, the compound represented by Chemical Formula 13 may be represented by Chemical Formula 13-1.

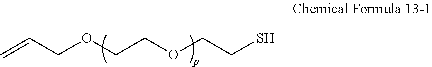

In Chemical Formula 13-1,
p is an integer from 0 to 10.

The curable composition may be a solvent-free curable composition.

The solvent-free curable composition may include about 5 wt % to about 60 wt % of the quantum dot and about 40 wt % to about 95 wt % of the polymerizable compound, based on a total amount of the solvent-free curable composition.

In one or more embodiments, the curable composition may further include a polymerization initiator, a light diffusing agent, a polymerization inhibitor and/or a (e.g., any suitable) combination thereof.

The light diffusing agent may include barium sulfate, calcium carbonate, titanium dioxide, zirconia, and/or a (e.g., any suitable) combination thereof.

The quantum dot may include a cadmium-free light emitting material.

In one or more embodiments, the quantum dot may have a core/shell structure of InP/ZnS or a core/first shell/second shell structure of InP/ZnSe/ZnS.

In one or more embodiments, the quantum dot may include: a core including Ag, In, Ga, and S; and a shell including at least two selected from among Ag, Ga, Zn, and S.

In one or more embodiments, the curable composition may further include: malonic acid; 3-amino-1,2-propanediol; a silane coupling agent; a leveling agent; a fluorinated surfactant; and/or a (e.g., any suitable) combination thereof.

In one or more embodiments, the curable composition may further include a solvent.

In one or more embodiments, the curable composition may include: about 1 wt % to about 40 wt % of the quantum dot; about 1 wt % to about 20 wt % of the polymerizable compound; and about 40 wt % to about 80 wt % of the solvent, based on a total weight of the curable composition.

According to one or more embodiments of the present disclosure, there is provided a cured layer produced using the curable composition.

According to one or more embodiments of the present disclosure, there is provided a display device including the cured layer.

Other embodiments of the present disclosure will be described in the following detailed description.

By surface-modifying quantum dots in a quantum dot-containing curable composition with a quantum dot surface-modifying material having a specific composition, the reliability and optical properties of the quantum dot-containing curable composition are improved. For example, this surface modification enhances the stability and dispersibility of the quantum dots, allowing for better integration into polar systems such as binders or curable monomers. As a result, the curable composition exhibits superior heat resistance and light resistance, addressing the limitations of existing quantum dot dispersions. Furthermore, the solvent-free nature of the composition helps avoid issues related to solvent volatilization, nozzle drying, and clogging during ink-jetting processes, ensuring consistent film thickness and processability. The inclusion of various agents such as malonic acid, 3-amino-1,2-propanediol, silane coupling agents, leveling agents, and fluorinated surfactants further contributes to the enhanced performance of the composition. Ultimately, this innovation leads to the development of cured layers and display devices with improved optical properties and reliability, making it suitable for advanced applications in display technology.

### DETAILED DESCRIPTION

Hereinafter, embodiments of the present disclosure will be described in more detail. However, these embodiments are mere example, and this disclosure is not limited thereto.

As used herein, if (e.g., when) a specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C7 to C20 arylalkyl group, “alkylene group” refers to a C1 to C20 alkylene group, “arylene group” refers to a C6 to C20 arylene group, “alkylarylene group” refers to a C7 to C20 alkylarylene group, “heteroarylene group” refers to a C3 to C20 heteroarylene group, and “alkoxy group” refers to a C1 to C20 alkoxy group.

As used herein, if (e.g., when) a specific definition is not otherwise provided, “substituted” refers to replacement of at least one hydrogen of a compound or a group by a substituent selected from among a halogen (F, Cl, Br, or I), a hydroxyl group, a C1 to C20 alkoxy group, a nitro group, a cyano group, an amine group, an imino group, an azido group, an amidino group, a hydrazino group, a hydrazono group, a carbonyl group, a carbamoyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, and/or a (e.g., any suitable) combination thereof.

As used herein, if (e.g., when) a specific definition is not otherwise provided, “hetero” refers to inclusion of at least one heteroatom selected from among N, O, S, and P, in the chemical formula.

As used herein, if (e.g., when) a specific definition is not otherwise provided, “(meth)acrylate” refers to both “acrylate” and “methacrylate,” and “(meth)acrylic acid” refers to “acrylic acid” and “methacrylic acid.”

As used herein, if (e.g., when) a specific definition is not otherwise provided, the term “combination” refers to mixing or copolymerization.

As used herein, if (e.g., when) a definition is not otherwise provided, hydrogen is bonded at the position if (e.g., when) a chemical bond is not drawn in chemical formula where supposed to be given.

In addition, as used herein, if (e.g., when) a definition is not otherwise provided, “*” refers to a linking point with the same or different atom or chemical formula.

A quantum dot-containing curable composition according to one or more embodiments of the present disclosure may use a surface-modifying material with a specific structure to surface-modify the quantum dot, achieving high heat/light resistance, compared to a general quantum dot-containing curable composition in the related art.

According to the recent development in in the display field where a light source is being shifted from an organic light-emitting diode (OLED) to micro light-emitting diode (LED), light resistance of a film mounted inside a display becomes more important than ever. Accordingly, light resistance of a cured layer formed by curing a quantum dot-containing curable composition also becomes very important, but a quantum dot surface-modifying material commonly used in the related fails in securing excellent or suitable film light resistance, for example, the film light resistance not enough to be used for the micro LED light source.

In general, in order to improve a curing rate of a quantum dot-containing curable composition, a high-sensitivity initiator or a multi-functional monomer, and/or the like are additionally used, and the resulting quantum dot-containing curable composition, which select a specific configuration, may improve one characteristic among all characteristics of the quantum dot-containing curable composition such as dispersion, heat resistance, and the curing rate but deteriorates the other characteristics excluding the improved characteristic. For example, regarding the characteristics of the quantum dot-containing curable composition, there has been no suitable technology for a quantum dot-containing curable composition capable of maintaining low viscosity and realizing high light resistance.

For example, the technology suitable so far includes a method of encapsulating the surfaces of quantum dots with a polymer including a heat-resistant functional group or a siloxane (or tetraethyl orthosilicate (TEOS), and/or the like)-based organic material, and/or the like. or encapsulating the surfaces of the quantum dots with aluminum, titanium, or an oxide thereof. In addition, attempts and efforts have recently been made to concurrently (e.g., simultaneously) increase luminance and durability by doping a small amount of a transition metal (Cu, Mg, and/or the like) component in the quantum dot synthesis.

However, the above methods are still under development and academic study and far away to actually apply to a display. In general, for displays that use quantum dots, efforts have been made to increase the intensity of the light source to improve luminance. However, if the luminance is improved by increasing the intensity of the light source, the stability of the quantum dot particles will decrease, which inevitably leads to the technical challenge of improving the reliability of the display (e.g., display panel).

Here, the present disclosure provides a curable composition that has excellent or suitable heat/light resistance reliability by increasing the dispersibility of quantum dots.

According to one or more embodiments of the present disclosure, a curable composition includes: (A) a quantum dot including a first functional group represented by Chemical Formula 1 and a second functional group having a different structure from the first functional group; and (B) a polymerizable compound.

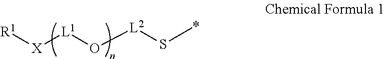

In Chemical Formula 1,
X may be sulfur or oxygen,
R¹ may be a monovalent functional group including a reactive group and a C3 to C20 cycloalkane ring,
L¹ and L² may each independently be a substituted or unsubstituted C1 to C20 alkylene group, and
n may be an integer between 2 and 10.

For example, in one or more embodiments, in Chemical Formula 1, n may be an integer from 2 to 8.

For example, the reactive group may include a carbon-carbon double bond, an epoxy group, and/or a (e.g., any suitable) combination thereof.

Hereinafter, each component constituting the curable composition according to one or more embodiments will be described in more detail.

### Quantum Dots

The most efficient ligand capable of passivating the surfaces of quantum dots and also being an organic material ligand is, as is well studied, a ligand having a thiol group; for example, a carboxylic acid-type (kind) ligand has relatively weak interaction with the surfaces of the quantum dots, and a phosphoric acid-type (kind) ligand has sufficient dispersibility of the quantum dots but a problem of lowering efficiency (causing color changes).

Because display technologies have been developed from liquid crystal display (LCD) in the past to OLED, nano emissive display (NED), and recent micro LED, which gradually increase intensity of blue light, the durability (particularly heat resistance and light resistance) of the quantum dots needs to be significantly improved, compared with the current level.

Accordingly, one or more embodiments of the present disclosure introduce two types (kinds) of ligands having different structures for effective passivation of the quantum dot surface. For example, one or more embodiments of the present disclosure provide a curable composition including quantum dots surface-modified with two types (kinds) of ligands by applying a first ligand, which is controlled or selected to have a structure of applying a thiol-based ligand having high binding energy with the quantum dot surface and including a bulky cycloalkyl group (including a fused ring group) having a carbon-carbon double bond and/or an epoxy group as a reactive group at the terminal end and concurrently (e.g., simultaneously), including an oxyalkylene group with high polarity necessarily included as a linking group between the thiol group and the cycloalkyl group, with a second ligand having a different structure from that of the first ligand, so that

if (e.g., when) mounted on a display panel as a single film, the curable composition including quantum dots surface-modified with these two types (kinds) of ligands may maintain initial light efficiency, even if (e.g., when) exposed to blue light such as micro LED for a long time, thereby achieving very excellent or suitable heat/light resistance reliability. The oxyalkylene group with high polarity may improve dispersibility of the quantum dots, and under this premise, the light resistance reliability may be improved by the reactive group attached to the bulky cycloalkyl group (including a fused ring group) at the terminal end. If (e.g., when) other linking groups such as an ester group and/or the like are included as the linking group in addition to the oxyalkylene group, the dispersibility of the quantum dots may not only be deteriorated, but also heat resistance, light resistance, optical properties, and/or the like may be deteriorated. Furthermore, if (e.g., when) the second ligand is controlled or selected to be an acidic ligand, as described in more detail later, for example, having a structure represented by Chemical Formula 2, the second ligand may bring about a synergistic effect with the first ligand represented by Chemical Formula 1, thereby maximizing or further increasing the light resistance reliability improvement.

For example, the present disclosure introduces a curable composition that includes quantum dots surface-modified with two types of ligands for effective passivation. The first ligand represented by Chemical Formula 1 is thiol-based with high binding energy and includes a bulky cycloalkyl group with a reactive group at the terminal end, linked by an oxyalkylene group. The second ligand represented by Chemical Formula 2 has a different structure and may be an acidic ligand. This combination improves the dispersibility and stability of the quantum dots, enhancing the heat and light resistance reliability of the composition. When used in display panels, the composition maintains initial light efficiency even under prolonged exposure to blue light, making it suitable for advanced display technologies.

For example, in one or more embodiments, in Chemical Formula 1, R¹ may be represented by any one selected from among Chemical Formulas R-1 to R-3.

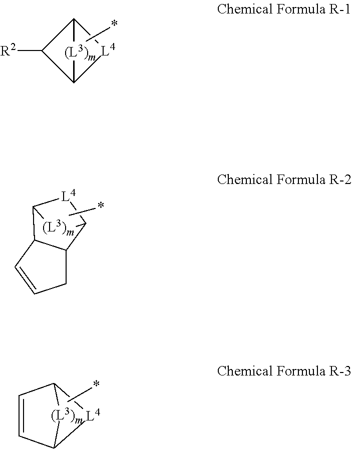

In Chemical Formulas R-1 to R-3,
R² may be a substituted or unsubstituted vinyl group, a substituted or unsubstituted epoxy group, or a C1 to C20 alkyl group substituted with an epoxy group, and/or a vinyl group,
L³ and L⁴ may each independently be a substituted or unsubstituted C1 to C10 alkylene group, and
m may be an integer of 0 or 1.

Because the bulkier the cycloalkane ring of R¹ is, the better it can protect the quantum dots from external light, it is advantageous for R¹ to be in the form of a fused ring including a cycloalkane ring, and therefore, in one or more embodiments, in Chemical Formulas R-1 and R-2, m may be an integer of 1. In these embodiments, it may also be advantageous in terms of improving reliability.

For example, in one or more embodiments, the first functional group represented by Chemical Formula 1 may be represented by any one selected from among Chemical Formula 1-1 to Chemical Formula 1-4, but embodiments of the present disclosure are not necessarily limited thereto.

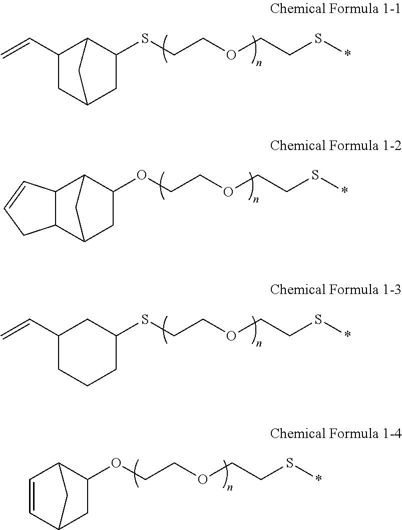

In Chemical Formula 1-1 to Chemical Formula 1-4,
n may be an integer from 2 to 10, for example, an integer from 2 to 8.

In one or more embodiments, the first functional group represented by Chemical Formula 1 may be derived from a compound represented by Chemical Formula 11.

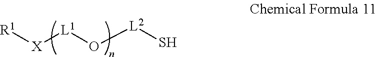

In Chemical Formula 11,
X may be sulfur or oxygen,
R¹ may be a monovalent functional group including a reactive group and a C3 to C20 cycloalkane ring,
L¹ and L² may each independently be a substituted or unsubstituted C1 to C20 alkylene group, and
n may be an integer from 2 to 10, for example, an integer from 2 to 8.

For example, a curable composition according to one or more embodiments may include: (A) a quantum dot surface-modified with a surface-modifying material; and (B) a polymerizable compound, wherein the surface-modifying material may include a compound (e.g., first compound) represented by Chemical Formula 11 and another compound (e.g., second compound) having a structure different from the Chemical Formula 11.

The definition of R¹ may be the same as described above. For example, in Chemical Formula 11, the definitions of the reactive groups, R¹, L¹, L², and n may also be the same as described above.

In one or more embodiments, the compound represented by Chemical Formula 11 may be represented by any one selected from among Chemical Formula 11-1 to Chemical Formula 11-4, but embodiments of the present disclosure are not necessarily limited thereto.

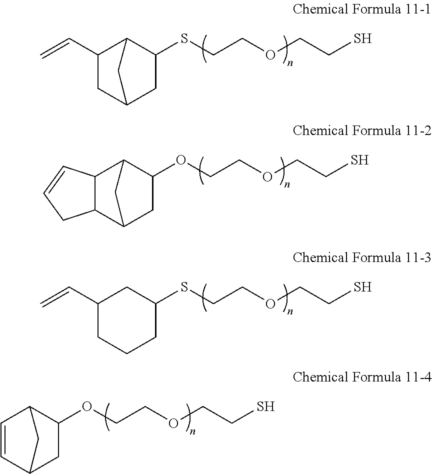

In Chemical Formula 11-1 to Chemical Formula 11-4,
n may be an integer between 2 and 10.

In one or more embodiments, the second functional group having a different structure from the first functional group may be represented by Chemical Formula 2 or Chemical Formula 3.

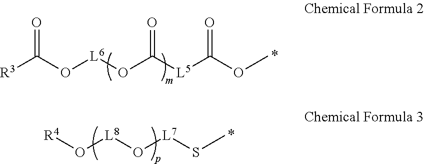

In Chemical Formula 2 and Chemical Formula 3,
R³ and R⁴ may each independently be a substituted or unsubstituted vinyl group, a substituted or unsubstituted epoxy group, or a C1 to C20 alkyl group substituted with an epoxy group and/or a vinyl group,
L⁵ to L⁸ may each independently be a substituted or unsubstituted C1 to C20 alkylene group, and
m and p may each independently be an integer from 0 to 10.

In one or more embodiments, the second functional group represented by Chemical Formula 2 may be represented by either Chemical Formula 2-1 or Chemical Formula 2-2, but embodiments of the present disclosure are not necessarily limited thereto.

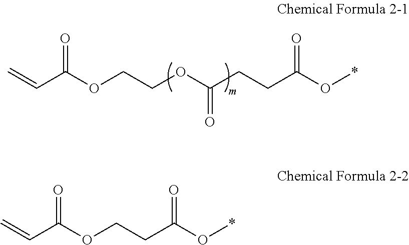

In Chemical Formula 2-1,
m may be an integer from 1 to 10.

In one or more embodiments, the second functional group represented by Chemical Formula 3 may be represented by Chemical Formula 3-1, but embodiments of the present disclosure are not necessarily limited thereto.

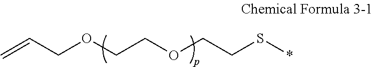

In Chemical Formula 3-1,
p may be an integer from 0 to 10.

In one or more embodiments, the second functional group may be derived from a compound represented by Chemical Formula 12 or Chemical Formula 13.

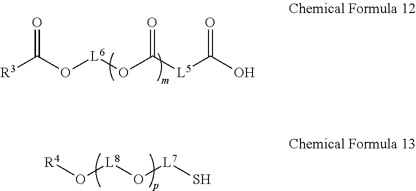

In Chemical Formula 12 and Chemical Formula 13,
R³ and R⁴ may each independently be a substituted or unsubstituted vinyl group, a substituted or unsubstituted epoxy group, or a C1 to C20 alkyl group substituted with an epoxy group and/or a vinyl group,
L⁵ to L⁸ may each independently be a substituted or unsubstituted C1 to C20 alkylene group, and
m and p may each independently be an integer from 0 to 10.

In one or more embodiments, the compound represented by Chemical Formula 12 may be represented by either Chemical Formula 12-1 or Chemical Formula 12-2.

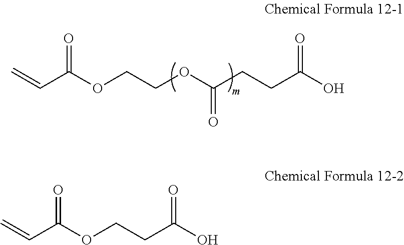

In Chemical Formula 12-1,
m may be an integer from 1 to 10.

In one or more embodiments, the compound represented by Chemical Formula 13 may be represented by Chemical Formula 13-1.

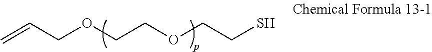

In Chemical Formula 13-1,
p may be an integer from 0 to 10.

If (e.g., when) the quantum dots surface-modified with the surface-modifying material are added to a polymerizable compound that will be described in more detail later and stirred, a very transparent dispersion may be obtained, which is a criterion for confirming that the surface-modification of the quantum dots is very good or suitable.

In one or more embodiments, the quantum dot may have a maximum fluorescence emission wavelength between about 500 nm and about 680 nm.

For example, when the curable composition according to one or more embodiments is a solvent-free curable composition, the quantum dots may be included in an amount of about 5 wt % to about 60 wt %, for example about 10 wt % to about 60 wt %, for example about 20 wt % to about 60 wt %, for example about 30 wt % to about 50 wt %, based on a total amount of the curable composition. If (e.g., when) the quantum dots are included within these ranges, a high light retention rate and light efficiency may be achieved even after curing.

For example, when the curable composition according to one or more embodiments is a curable composition including a solvent, the quantum dots may be included in an amount of about 1 wt % to about 40 wt %, for example, about 3 wt % to 30 about wt %, based on a total amount of the curable composition. If (e.g., when) the quantum dots are included within the above ranges, the light conversion rate is improved and pattern characteristics and development characteristics are not impaired, so that excellent or suitable processability may be obtained.

Up to now, quantum dot-containing curable compositions (inks) have been developed by specializing in thiol-based binders or monomers that have good or suitable compatibility with quantum dots, and are even being commercialized.

For example, the quantum dots absorb light in a wavelength region of about 360 nm to about 780 nm, for example about 400 nm to about 780 nm and emits fluorescence in a wavelength region of about 500 nm to about 700 nm, for example about 500 nm to about 580 nm, or emits fluorescence in a wavelength region of about 600 nm to about 680 nm. For example, in one or more embodiments, the quantum dots may have a maximum fluorescence emission wavelength (fluorescence λₑₘ) at about 500 nm to about 680 nm.

The quantum dots may each independently have a full width at half maximum (FWHM) of emission spectrum of about 20 nm to about 100 nm, for example about 20 nm to about 50 nm. If (e.g., when) the quantum dots have a full width at half maximum (FWHM) of the ranges, color reproducibility is increased when used as a color material in a color filter due to high color purity.

The quantum dots may each independently be an organic material, an inorganic material, or a hybrid (mixture) of an organic material and an inorganic material.

The quantum dots may each independently be composed of a core and a shell around (e.g., surrounding) the core, and the core and the shell may each independently have a structure of a core, a core/shell, a core/first shell/second shell, an alloy, an alloy/shell, and/or the like, which is composed of a Group II-IV compound, a Group III-V compound, and/or the like, but embodiments of the present disclosure are not limited thereto.

For example, in one or more embodiments, the core may include at least at least one material selected from among CdS, CdSe, CdTe, ZnS, ZnSe, ZnTe, HgS, HgSe, HgTe, GaN, GaP, GaAs, InP, InAs, and an alloy thereof, but embodiments of the present disclosure are not necessarily limited thereto. The shell around (e.g., surrounding) the core may include at least at least one material selected from among CdSe, ZnSe, ZnS, ZnTe, CdTe, PbS, TiO₂, SrSe, HgSe, and an alloy thereof, but embodiments of the present disclosure are not necessarily limited thereto.

In one or more embodiments, because an interest in environment protection has been recently increased over the world, and a restriction of a toxic material has been agreed on and fortified, a cadmium-free light emitting material (InP/ZnS, InP/ZnSe/ZnS, and/or the like.) having relatively low quantum efficiency (quantum yield) but being environmentally-friendly instead of a light emitting material having a cadmium-based core is employed, but embodiments of the present disclosure are not necessarily limited thereto.

In one or more embodiments, the quantum dot may be a quantum dot including: a core including Ag, In, Ga, and S; and a shell including at least two (or at least three) selected from among Ag, Ga, Zn, and S. In this regard, the quantum dot may have one or more ligands. For example, the quantum dot may include, but is not necessarily limited to, a first ligand including a halide, a second ligand including an alkyl group and/or an alkoxy amine group, or a ligand of a combination thereof, but embodiments of the present disclosure are not necessarily limited thereto.

In embodiments of the quantum dots with the core/shell structure, an entire size including the shell (an average particle diameter) may be about 1 nm to about 15 nm, for example, about 5 nm to about 15 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

For example, in one or more embodiments, the quantum dots may each independently include red quantum dots (e.g., quantum dots that emits red light), green quantum dots (e.g., quantum dots that emits blue light), and/or a (e.g., any suitable) combination thereof. The red quantum dots may each independently have an average particle diameter of about 10 nm to about 15 nm. The green quantum dots may each independently have an average particle diameter of about 5 nm to about 8 nm.

In addition, for dispersion stability of the quantum dot, the curable composition according to one or more embodiments may further include a dispersant. The dispersant helps uniform dispersibility of light conversion materials such as quantum dots in the curable composition and may include a non-ionic dispersant, an anionic dispersant, or a cationic dispersant. For example, the dispersant may be polyalkylene glycol or an ester thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine, and/or the like, and they may be used alone or in a mixture of two or more. The dispersant may be used in an amount of about 0.1 wt % to 100 wt %, for example about 10 wt % to about 20 wt %, based on a solid content (e.g., amount) of the light conversion material such as quantum dots.

### Polymerizable Compound

The curable composition according to one or more embodiments may include a polymerizable compound, and the polymerizable compound may have a carbon-carbon double bond at its terminal end.

The polymerizable compound having the carbon-carbon double bond at the terminal end may be included in an amount of about 40 wt % to about 95 wt %, for example, about 50 wt % to about 90 wt %, based on a total amount of the solvent-free curable composition. If (e.g., when) the polymerizable compound having the carbon-carbon double bond at the terminal end is included within the ranges, the solvent-free curable composition having a viscosity that enables ink-jetting may be prepared and the quantum dots in the prepared solvent-free curable composition may have improved dispersibility, thereby improving optical characteristics.

For example, the polymerizable compound having the carbon-carbon double bond at the terminal end may have a molecular weight (e.g., weight averaged molecular weight) of about 170 g/mol to about 1,000 g/mol. If (e.g., when) the polymerizable compound having the carbon-carbon double bond at the terminal end has a molecular weight within the range, it may be advantageous for ink-jetting because it does not increase a viscosity of the composition and not hinder the optical characteristics of the quantum dots.

For example, in one or more embodiments, the polymerizable compound having the carbon-carbon double bond at the terminal end may be represented by Chemical Formula 4, but embodiments of the present disclosure are not necessarily limited thereto.

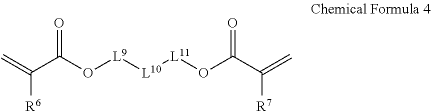

In Chemical Formula 4,
R⁶ and R⁷ may each independently be hydrogen or a substituted or unsubstituted C1 to C10 alkyl group,
L⁹ and L¹¹ may each independently be a single bond or a substituted or unsubstituted C1 to C10 alkylene group, and
L¹⁰ may be a substituted or unsubstituted C1 to C10 alkylene group, a substituted or unsubstituted C3 to C20 cycloalkylene group, or an ether group (*—O—*).

For example, in one or more embodiments, the polymerizable compound having the carbon-carbon double bond at the terminal end may be represented by Chemical Formula 4-1, Chemical Formula 4-2, or Chemical Formula 4-3, but embodiments of the present disclosure are not necessarily limited thereto.

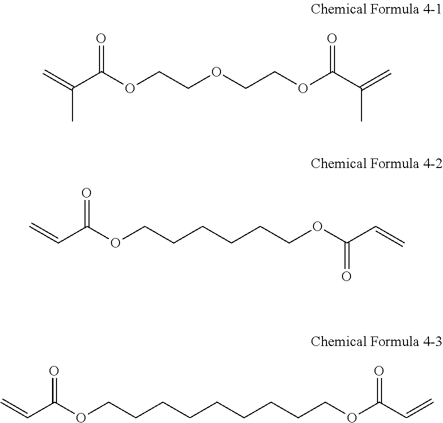

For example, in one or more embodiments, the polymerizable compound having the carbon-carbon double bond at the terminal end may further include ethylene glycoldiacrylate, triethylene glycoldiacrylate, 1,4-butanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolac epoxyacrylate, ethylene glycoldimethacrylate, triethylene glycoldimethacrylate, propylene glycoldimethacrylate, 1,4-butanedioldimethacrylate, 1,6-hexanedioldimethacrylate, and/or a (e.g., any suitable) combination thereof in addition to the aforementioned compound of Chemical Formula 4-1, Chemical Formula 4-2, or Chemical Formula 4-3.

In one or more embodiments, together with the polymerizable compound having the carbon-carbon double bond at the terminal end, a generally-used monomer of a thermosetting or photocurable composition may be further included. For example, the monomer further includes an oxetane-based compound such as bis[1-ethyl (3-oxetanyl)]methyl ether, and/or the like.

In one or more embodiments, if (e.g., when) the curable composition includes a solvent, the polymerizable compound may be included in an amount of about 1 wt % to about 20 wt %, about 1 wt % to about 15 wt %, for example, about 5 wt % to about 15 wt %, based on a total amount of the curable composition. When the above polymerizable compound is included within the above ranges, the optical properties of the quantum dot may be improved, and in the pattern formation process, sufficient curing occurs upon exposure, so that reliability is improved, and the heat resistance, light resistance, chemical resistance, resolution, and adhesion of the pattern are also improved.

In one or more embodiments, if (e.g., when) the curable composition includes a solvent, the polymerizable compound may be a monofunctional ester or a polyfunctional ester of (meth)acrylic acid having at least one ethylenically unsaturated double bond.

Because the polymerizable compound has the ethylenically unsaturated double bond, sufficient polymerization occurs upon exposure in a pattern forming process, thereby forming a pattern having excellent or suitable heat resistance, light resistance, and chemical resistance.

Non-limiting examples of the polymerizable compound used in the solvent-type (kind) curable composition may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolacepoxy (meth)acrylate, and/or the like.

Non-limiting examples of commercially available products of the polymerizable compound are as follows. Non-limiting examples of the monofunctional esters of the (meth)acrylic acid may include Aronix M-101®, M-111®, M-114® from Toagosei Chemical Industry Co., Ltd.; KAYARAD TC-110S®, TC-120S® from Nihon Kayaku Co., Ltd.; V-158®, V-2311® from Osaka Yuki Chemical Industry Co., Ltd. Non-limiting examples of the bifunctional esters of the (meth)acrylic acid include Aronix M-210®, M-240®, M-6200® from Toagosei Chemical Industry Co., Ltd.; KAYARAD HDDA®, HX-220®, R-604® from Nihon Kayaku Co., Ltd.; V-260®, V-312®, V-335 HP® from Osaka Yuki Chemical Industry Co., Ltd. Non-limiting examples of the trifunctional ester of the (meth)acrylic acid may include Aronix M-309®, DONG M-400®, DONG M-405®, DONG M-450@, DONG M-7100®, DONG M-8030®, DONG M-8060®, and/or the like from Toagosei Chemical Industry Co., Ltd.; KAYARAD TMPTA®, DONG DPCA-20®, DONG-30®, DONG-60®, DONG-120®, and/or the like from Nihon Kayaku Co., Ltd.; V-295®, DONG-300®, DONG-360®, DONG-GPT®, DONG-3PA®, DONG-400®, and/or the like from Osaka Yuki Kayaku Industry Co., Ltd. These products may be used alone or in combination of two or more.

The polymerizable compound may also be used by treating it with an acid anhydride to provide better developability.

### Light Diffusing Agent

The curable composition according to one or more embodiments may further include a light diffusing agent.

For example, the light diffusing agent may include barium sulfate (BaSO₄), calcium carbonate (CaCO₃), titanium dioxide (TiO₂), zirconia (ZrO₂), and/or a (e.g., any suitable) combination thereof.

The light diffusing agent may reflect unabsorbed light in the aforementioned quantum dots and allows the quantum dots to absorb the reflected light again. For example, the light diffusing agent may increase an amount of light absorbed by the quantum dots and increase light conversion efficiency of the curable composition.

The light diffusing agent may have an average particle diameter (D50) of about 150 nm to about 250 nm, for example, about 180 nm to about 230 nm. If (e.g., when) the average particle diameter of the light diffusing agent is within the ranges, it may have a better light diffusing effect and increase light conversion efficiency.

The light diffusing agent may be included in an amount of about 1 wt % to about 20 wt %, for example, about 2 wt % to about 15 wt %, for example, about 2 wt % to about 10 wt %, based on a total amount of the curable composition. If (e.g., when) the light diffusing agent is included in an amount of less than 1 wt % based on a total amount of the curable composition, it is difficult to expect a light conversion efficiency improvement effect due to the use of the light diffusing agent, while if (e.g., when) it is included in an amount of greater than 20 wt %, there is a possibility that the quantum dots may be sedimented.

### Polymerization Initiator

The curable composition according to one or more embodiments may further include a polymerization initiator, for example, a photopolymerization initiator, a thermal polymerization initiator, and/or a (e.g., any suitable) combination thereof.

The photopolymerization initiator may be a generally-used initiator for a photosensitive resin composition, for example, an acetophenone-based compound, a benzophenone-based compound, a thioxanthone-based compound, a benzoin-based compound, a triazine-based compound, an oxime-based compound, an aminoketone-based compound, and/or the like, but embodiments of the present disclosure are not necessarily limited thereto.

Non-limiting examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

Non-limiting examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

Non-limiting examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and/or the like.

Non-limiting examples of the benzoin-based compound may be benzoin, benzoin methyl ether, benzoin ethyl ether, benzoin isopropyl ether, benzoin isobutyl ether, benzyldimethylketal, and/or the like.

Non-limiting examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

Non-limiting examples of the oxime-based compound may be an O-acyloxime-based compound, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and/or the like. Non-limiting examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and/or the like.

Non-limiting examples of the aminoketone-based compound may be 2-benzyl-2-dimethylamino-1-(4-morpholinophenyl)-butanone-1, and/or the like.

The photopolymerization initiator may further include a carbazole-based compound, a diketone-based compound, a sulfonium borate-based compound, a diazo-based compound, an imidazole-based compound, a biimidazole-based compound, and/or the like, besides the photopolymerization initiator compounds described above.

The photopolymerization initiator may be used with a photosensitizer capable of causing a chemical reaction by absorbing light and becoming excited and then, transferring its energy.

Non-limiting examples of the photosensitizer may be tetraethylene glycol bis-3-mercapto propionate, pentaerythritol tetrakis-3-mercapto propionate, dipentaerythritol tetrakis-3-mercapto propionate, and/or the like.

Non-limiting examples of the thermal polymerization initiator may be a peroxide, for example, benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, t-butyl perbenzoate, and/or the like, and/or an azo-containing compound, for example, 2,2-azo-bis(isobutyronitrile), 2,2′-azobis-2-methylpropinonitrile, but embodiments of the present disclosure are not necessarily limited thereto, and any of which is well suitable in the art may be used.

The polymerization initiator may be included in an amount of about 0.01 wt % to about 10 wt %, for example, about 2 wt % to about 8 wt % based on a total amount of the curable composition. If (e.g., when) the polymerization initiator is included in the ranges, it may obtain excellent or suitable reliability due to sufficient curing during exposure or thermal curing and to prevent or reduce deterioration of transmittance due to non-reaction initiators, thereby preventing or reducing deterioration of optical characteristics of the quantum dots.

### Binder Resin

The curable composition according to one or more embodiments may further include a binder resin.

The binder resin may include an acrylic resin, a cardo-based resin, an epoxy resin, and/or a (e.g., any suitable) combination thereof.

The acrylic resin may be a copolymer of a first ethylenic unsaturated monomer and a second ethylenic unsaturated monomer that is copolymerizable therewith, and may be a resin including at least one acryl-based repeating unit.

Non-limiting examples of the acrylic resin may be polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and/or the like, and these copolymers may be used alone or as a mixture of two or more.

A weight average molecular weight of the acrylic resin may be about 5,000 g/mol to about 15,000 g/mol. If (e.g., when) the acrylic resin has a weight average molecular weight within the ranges, close contacting properties to a substrate, and physical and chemical properties are improved, and a viscosity of the acrylic resin is appropriate or suitable.

An acid value of the acrylic resin may be about 80 mgKOH/g to about 130 mgKOH/g. If (e.g., when) the acrylic resin has an acid value within the ranges, excellent or suitable resolution of a pixel may be obtained.

The cardo-based resin may be used in a curable resin (or photosensitive resin) composition, for example, one suggested in Korean Patent Publication No. 10-2018-0067243 may be used, the entire content of which is incorporated herein by reference, but embodiments of the present disclosure are not limited thereto.

The cardo-based resin may be, for example prepared by mixing at least two selected from among a fluorene-containing compound such as 9,9-bis(4-oxiranylmethoxyphenyl) fluorene; an anhydride compound such as benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and tetrahydrophthalic anhydride; a glycol compound such as ethylene glycol, propylene glycol, and polyethylene glycol; an alcohol compound such as methanol, ethanol, propanol, n-butanol, cyclohexanol, and benzylalcohol; a solvent-based compound such as propylene glycol methylethylacetate, and N-methylpyrrolidone; a phosphorus compound such as triphenylphosphine; and an amine or ammonium salt compound such as tetramethylammonium chloride, tetraethylammonium bromide, benzyldiethylamine, triethylamine, tributylamine, and/or benzyl triethylammonium chloride.

A weight average molecular weight of the cardo-based binder resin may be about 500 g/mol to about 50,000 g/mol, for example about 1,000 g/mol to about 30,000 g/mol. If (e.g., when) the weight average molecular weight of the cardo-based binder resin is within the ranges, a satisfactory pattern may be formed without a residue during a production of a cured layer and without losing a film thickness during development of the curable composition.

If (e.g., when) the binder resin is a cardo-based resin, the curable composition including the same, the photosensitive resin composition may have excellent or suitable developability and sensitivity during photo-curing and thus, fine pattern-forming capability.

The epoxy resin may be a thermally polymerizable monomer or oligomer, and may include a compound having a carbon-carbon unsaturated bond and a carbon-carbon cyclic bond.

The epoxy resin may further include a bisphenol A epoxy resin, a bisphenol F epoxy resin, a phenol novolac epoxy resin, a cyclic aliphatic epoxy resin, and/or an aliphatic polyglycidyl ether, but embodiments of the present disclosure are not necessarily limited thereto.

As commercially available products of the compounds, a bisphenyl epoxy resin may be YX4000, YX4000H, YL6121H, YL6640, and/or YL6677 of Yuka Shell Epoxy Co., Ltd.; a cresol novolac epoxy resin may be EOCN-102, EOCN-103S, EOCN-104S, EOCN-1020, EOCN-1025, and/or EOCN-1027 of Nippon Kayaku Co., Ltd. and EPIKOTE 180S75, and/or the like of Yuka Shell Epoxy Co., Ltd.; a bisphenol A epoxy resin may be EPIKOTE 1001, 1002, 1003, 1004, 1007, 1009, 1010, and/or 828 of Yuka Shell Epoxy Co., Ltd.; a bisphenol F epoxy resin may be EPIKOTE 807 and/or 834 of Yuka Shell Epoxy Co., Ltd.; a phenol novolac epoxy resin may be EPIKOTE 152, 154, and/or 157H65 of Yuka Shell Epoxy Co. and/or EPPN 201, 202 of Nippon Kayaku Co., Ltd. And/or EPPN 201, 202 of Nippon Kayaku Co., Ltd.; a cyclic aliphatic epoxy resin may be CY175, CY177, and/or CY179 of CIBA-GEIGY A.G Corp., ERL-4234, ERL-4299, ERL-4221, and/or ERL-4206 of U.C.C., Showdyne 509 of Showa Denko K.K., Araldite CY-182, CY-192 and/or CY-184 of CIBA-GEIGY A.G Corp., EPICLON 200 and/or 400 of Dainippon Ink & Chemicals Inc., EPIKOTE 871 and/or 872, and EP1032H60 of Yuka Shell Epoxy Co., Ltd., ED-5661 and/or ED-5662 of Celanese Coating Corporation; an aliphatic polyglycidylether may be EPIKOTE 190P and/or 191P of Yuka Shell Epoxy Co., Ltd., EPOLITE 100MF of Kyoeisha Yushi Kagaku Kogyo Co., Ltd., EPIOL TMP of Nihon Yushi K. K., and/or the like.

For example, if (e.g., when) the curable composition according to one or more embodiments is a solvent-free curable composition, the binder resin may be included in an amount of about 0.5 wt % to about 10 wt %, for example, about 1 wt % to about 5 wt %, based on a total amount of the curable composition. In these embodiments, the heat resistance and the chemical resistance of the solvent-free curable composition may be improved, as well as the storage stability of the curable composition.

For example, if (e.g., when) the curable composition according to one or more embodiments is a curable composition including a solvent, the binder resin may be included in an amount of about 1 wt % to about 30 wt %, for example, about 3 wt % to about 20 wt %, based on a total amount of the curable composition. In these embodiments, it may improve pattern characteristics, heat resistance, and chemical resistance.

### Other Additives

For stability and dispersion improvement of the quantum dots, the curable composition according to one or more embodiments may further include a polymerization inhibitor.

The polymerization inhibitor may include a hydroquinone-based compound, a catechol-based compound, and/or a (e.g., any suitable) combination thereof, but embodiments of the present disclosure are not necessarily limited thereto. When the curable composition according to one or more embodiments further includes the hydroquinone-based compound, the catechol-based compound, or any combination thereof, room temperature cross-linking during exposure after coating the curable composition may be prevented or reduced.

For example, the hydroquinone-based compound, the catechol-based compound, or any combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, and/or a (e.g., any suitable) combination thereof, but embodiments of the present disclosure are not necessarily limited thereto.

The hydroquinone-based compound, the catechol-based compound, or any combination thereof may be used in a form of dispersion. The polymerization inhibitor in a form of dispersion may be included in an amount of about 0.001 wt % to about 3 wt %, for example, about 0.01 wt % to about 2 wt %, based on a total amount of the curable composition. If (e.g., when) the polymerization inhibitor is included in the ranges, passage of time at room temperature may be solved and concurrently (e.g., simultaneously) sensitivity deterioration and surface delamination phenomenon may be prevented or reduced.

In addition, the curable composition according to one or more embodiments may further include malonic acid; 3-amino-1,2-propanediol; a silane-based coupling agent; a leveling agent; a fluorine-based surfactant; and/or a (e.g., any suitable) combination thereof in order to improve heat resistance and reliability.

For example, the curable composition according to one or more embodiments may further include a silane-based coupling agent having a reactive substituent such as a vinyl group, a carboxyl group, a methacryloxy group, an isocyanate group, an epoxy group, and/or the like in order to improve close contacting properties with a substrate.

Non-limiting examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, (β-epoxycyclohexyl)ethyltrimethoxysilane, and/or the like, and these may be used alone or in a mixture of two or more.

The silane-based coupling agent may be used in an amount of about 0.01 parts by weight to about 10 parts by weight based on 100 parts by weight of the curable composition. If (e.g., when) the silane-based coupling agent is included within the range, close contacting properties, storage capability, and/or the like are improved.

In one or more embodiments, the curable composition may further include a surfactant, for example, a fluorine-based surfactant as needed in order to improve coating properties and inhibit or reduce generation of spots, that is, improve leveling performance.

The fluorine-based surfactant may have a low weight average molecular weight of about 4,000 g/mol to about 10,000 g/mol, for example, about 6,000 g/mol to about 10,000 g/mol. In addition, the fluorine-based surfactant may have a surface tension of about 18 mN/m to about 23 mN/m (measured in a 0.1% polyethylene glycol monomethylether acetate (PGMEA) solution). If (e.g., when) the fluorine-based surfactant has a weight average molecular weight and a surface tension within the ranges, leveling performance may be further improved, and excellent or suitable characteristics may be provided when slit coating as high-speed coating is applied because film defects may be less generated by preventing or reducing a spot generation during the high-speed coating and suppressing or reducing a vapor generation.

Non-limiting examples of the fluorine-based surfactant may be, BM-1000®, and BM-1100® (BM Chemie Inc.); MEGAFACE F 142D®, F 172®, F 173®, and F 183® Dainippon Ink Kagaku Kogyo Co., Ltd.); FULORAD FC-135®, FULORAD FC-170C® FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145® (ASAHI Glass Co., Ltd.); and SH-28PA®, SH-190®, SH-193®, SZ-6032®, and SF-8428®, and/or the like (Toray Silicone Co., Ltd.); F-482, F-484, F-478, F-554 and/or the like of DIC Co., Ltd.

In addition, the curable composition according to one or more embodiments may include a silicone-based surfactant in addition to the fluorine-based surfactant. Non-limiting examples of the silicone-based surfactant may be TSF400, TSF401, TSF410, TSF4440, and/or the like of Toshiba silicone Co., Ltd., but embodiments of the present disclosure are not limited thereto.

The silicone-based surfactant may be included in an amount of about 0.01 parts by weight to about 5 parts by weight, for example, about 0.1 parts by weight to about 2 parts by weight based on 100 parts by weight of the curable composition. If (e.g., when) the silicone-based surfactant is included within the ranges, foreign materials are less produced in a sprayed composition.

In addition, the curable composition according to one or more embodiments may further include other additives such as an antioxidant, a stabilizer, and/or the like in a set or predetermined amount, unless properties are deteriorated.

### Solvent

In one or more embodiments, the curable composition may further include a solvent.

The solvent may, for example, include one or more selected from among alcohols such as methanol, ethanol, and/or the like; glycol ethers such as ethylene glycol methylether, ethylene glycol ethylether, propylene glycol methylether, and/or the like; cellosolve acetates such as methyl cellosolve acetate, ethyl cellosolve acetate, diethyl cellosolve acetate, and/or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and/or the like; propylene glycol alkylether acetates such as propylene glycol monomethylether acetate, propylene glycol propylether acetate, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; hydroxy acetic acid alkyl esters such as methyl hydroxyacetate, ethyl hydroxyacetate, butyl hydroxyacetate, and/or the like; acetic acid alkoxyalkyl esters such as methoxymethyl acetate, methoxyethyl acetate, methoxybutyl acetate, ethoxymethyl acetate, ethoxyethyl acetate, and/or the like; 3-hydroxypropionic acid alkyl esters such as methyl 3-hydroxypropionate, ethyl 3-hydroxypropionate, and/or the like; 3-alkoxypropionic acid alkyl esters such as methyl 3-methoxypropionate, ethyl 3-methoxypropionate, ethyl 3-ethoxypropionate, methyl 3-ethoxypropionate, and/or the like; 2-hydroxypropionic acid alkyl esters such as methyl 2-hydroxypropionate, ethyl 2-hydroxypropionate, propyl 2-hydroxypropionate, and/or the like; 2-alkoxypropionic acid alkyl esters such as methyl 2-methoxypropionate, ethyl 2-methoxypropionate, ethyl 2-ethoxypropionate, methyl 2-ethoxypropionate, and/or the like; 2-hydroxy-2-methylpropionic acid alkyl esters such as methyl 2-hydroxy-2-methylpropionate, ethyl 2-hydroxy-2-methylpropionate, and/or the like; 2-alkoxy-2-methylpropionic acid alkyl esters such as methyl 2-methoxy-2-methylpropionate, ethyl 2-ethoxy-2-methylpropionate, and/or the like; esters such as 2-hydroxyethyl propionate, 2-hydroxy-2-methylethyl propionate, hydroxyethyl acetate, methyl 2-hydroxy-3-methylbutanoate, and/or the like; and/or ketonate esters such as ethyl pyruvate, and/or the like, or may be N-methylformamide, N,N-dimethyl formamide, N-methylformanilide, N-methylacetamide, N, N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and/or the like, but embodiments of the present disclosure are not limited thereto.

For example, in one or more embodiments, the solvent may be desirably a glycol ether such as ethylene glycol monoethylether, ethylene diglycolmethylethylether, and/or the like; an ethylene glycol alkylether acetate such as ethyl cellosolve acetate, and/or the like; an ester such as 2-hydroxy ethyl propionate, and/or the like; a carbitol such as diethylene glycol monomethylether, and/or the like; a propylene glycol alkylether acetate such as propylene glycol monomethylether acetate, propylene glycol propylether acetate, and/or the like; an alcohol such as ethanol; cyclohexyl acetate; and/or a (e.g., any suitable) combination thereof.

For example, in one or more embodiments, the solvent may be a high-boiling point polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, cyclohexyl acetate, and/or a (e.g., any suitable) combination thereof.

The solvent may be included in an amount of about 40 wt % to about 80 wt %, for example, about 45 wt % to about 80 wt %, based on a total amount of the curable composition. If (e.g., when) the solvent is within the range, the solvent-type (kind) curable composition has appropriate or suitable viscosity and thus may have excellent or suitable coating property when coated in a large area through spin-coating and slit-coating.

one or more embodiments provide a cured layer produced using the aforementioned curable composition, a color filter including the cured layer, and a display device including the color filter. For example, the display device may include a micro LED light source.

One of the methods for producing the cured layer may include coating the curable composition or the solvent-type (kind) curable composition on a substrate using an ink-jet spraying method to form a pattern (S1); and curing the pattern (S2).

### (S1) Formation of Pattern

The curable composition may desirably be coated to be about 0.5 μm to about 20 μm on a substrate using an ink-jet spraying method. The ink-jet spraying method may form a pattern by spraying a single color per each nozzle and thus repeating the spraying as many times as the needed number of colors, but the pattern may be formed by concurrently (e.g., simultaneously) spraying the needed number of colors through each ink-jet nozzle in order to reduce processes.

### (S2) Curing

The obtained pattern is cured to obtain a pixel. Herein, the curing method may be a thermal curing process or a photocuring process. The thermal curing process may be performed at greater than or equal to about 100° C., desirably, in a range of about 100° C. to about 300° C., and more desirably, in a range of about 160° C. to about 250° C. The photocuring process may include irradiating an actinic ray such as a UV ray of 190 nm to 450 nm, for example, 200 nm to 400 nm. As light sources used in the irradiation, low-pressure mercury lamps, high-pressure mercury lamps, ultra-high-pressure mercury lamps, metal halide lamps, argon gas lasers, i-line, KrF, ArF, I—ArF, EUV, X-rays, and/or electron beams may be used depending on the case.

The other method of producing the cured layer may include producing a cured layer using the aforementioned curable composition by a lithography method as follows.

### (1) Coating and Film Formation

The aforementioned curable composition is coated to have a desired or suitable thickness, for example, a thickness in a range of about 2 μm to about 10 μm, on a substrate which undergoes a set or predetermined pretreatment, using a spin or slit coating method, a roll coating method, a screen-printing method, an applicator method, and/or the like. Then, the coated substrate is heated at a temperature of 70° C. to 90° C. for 1 minute to 10 minutes to remove a solvent and to form a film.

### (2) Exposure

The resultant film is irradiated by an actinic ray such as a UV ray of 190 nm to 450 nm, for example, 200 nm to 400 nm after putting a mask with a set or predetermined shape to form a desired or suitable pattern. As light sources used in the irradiation, low-pressure mercury lamps, high-pressure mercury lamps, ultra-high-pressure mercury lamps, metal halide lamps, argon gas lasers, i-line, KrF, ArF, I—ArF, EUV, X-rays, and/or electron beams may be used depending on the case.

Exposure process uses, for example, a light dose of about 500 mJ/cm² or less (with a 365 nm sensor) if (e.g., when) a high-pressure mercury lamp is used. However, the light dose may vary depending on types (kinds) of each component of the curable composition, its combination ratio, and a dry film thickness.

### (3) Development

After the exposure process, an alkali aqueous solution is used to develop the exposed film by dissolving and removing an unnecessary part except the exposed part, forming an image pattern. For example, when the alkali developing solution is used for the development, a non-exposed region is dissolved, and an image color filter pattern is formed.

### (4) Post-Treatment

The developed image pattern may be heated again or irradiated by an actinic ray and/or the like for curing, to accomplish excellent or suitable quality in terms of heat resistance, light resistance, close contacting properties, crack-resistance, chemical resistance, high strength, storage stability, and/or the like.

Hereinafter, the disclosure will be illustrated in more detail with reference to examples. These examples, however, are not in any sense to be interpreted as limiting the scope of the present disclosure.

### Synthesis of Surface-Modifying Materials

### First Ligand

### Synthesis Example 1-1

150.22 g of hydroxydicyclopentadiene and 0.1 g of KOH were placed in a high-pressure reactor, and the internal temperature was raised to 80° C. HDCP-4 was synthesized by slowly adding 176 g of ethylene oxide while controlling the internal pressure. 326.22 g of HDCP-4 was added in a two-neck round bottom flask and dissolved sufficiently in 800 mL of tetrahydrofuran (THF). At an internal temperature of 0° C., 44 g of NaOH and 100 ml of water were added and dissolved sufficiently until a clear solution was obtained. A solution of 210 g of para-toluene sulfonyl chloride dissolved in 300 mL of THE was slowly injected at 0° C. Here, the injection was performed for 2 hours, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 481.2 g of the obtained dried material was placed in a two-necked round bottom flask and stirred thoroughly in 500 mL of ethanol. Then, 91.2 g of thiourea was added thereto, dispersed, and refluxed at 80° C. for 12 hours. Then, an aqueous solution of 60 g of NaOH dissolved in 200 mL of water was injected, and after 5 more hours of reaction, an excessive amount of methylene chloride was added to dilute it. A hydrochloric acid solution was added and extraction, titration, moisture removal, and solvent removal were performed sequentially. By drying in a vacuum oven for 24 hours, a compound represented by Chemical Formula A-1 was obtained.

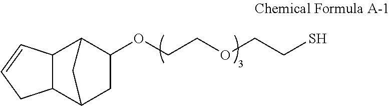

### Synthesis Example 1-2

120 g of 5-vinyl-2-norbornene, 78.1 g of 2-mercaptoethanol, 0.3 g of azobisisobutyronitrile (AIBN), and 150 g of methanol were added to a round flask, heated to 60° C., and reacted for 6 hours. The obtained compound was transferred to a high-pressure reactor, 0.1 g of KOH was added to the compound obtained above, and the internal temperature was increased to 80° C. 176 g of ethylene oxide was slowly added and reacted while controlling the internal pressure. The compound obtained here was placed in a two-neck round bottom flask and dissolved sufficiently in THF. At 0° C., 44 g of NaOH and 100 mL of water were added thereto and dissolved sufficiently until a clear solution was obtained. A solution of 210 g of para-toluene sulfonyl chloride dissolved in 300 mL of THF was slowly injected at 0° C. Here, the injection was performed for 2 hours, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. The obtained dried material was placed in a two-necked round bottom flask and stirred thoroughly in 500 mL of ethanol. Then, 91.2 g of thiourea was added thereto, dispersed, and refluxed at 80° C. for 12 hours. Then, an aqueous solution obtained by dissolving 60 g of NaOH in 200 ml of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula A-2 was obtained.

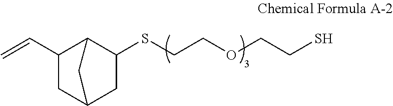

### Comparative Synthesis Example 1

100 g of polyethylene glycol ether (Hannong Chemicals Inc.) was placed in a two-neck round bottom flask and dissolved sufficiently in 300 mL of THF. 15.4 g of NaOH was added to 100 ml of water at 0° C. and then, dissolved therein, until a transparent solution was obtained. A solution of 73 g of para-toluene sulfonyl chloride dissolved in 100 mL of THF was slowly injected at 0° C. Here, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 50 g of the dried product was added in a two-necked round bottom flask and sufficiently stirred in 300 mL of ethanol. Subsequently, 27 g of thiourea was added thereto and dispersed and then, refluxed at 80° C. for 12 hours. Then, an aqueous solution obtained by dissolving 4.4 g of NaOH in 20 ml of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula W was obtained.

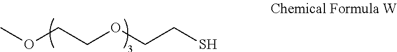

### Comparative Synthesis Example 2

100 g of polyethylene glycol phenyl ether (Hannong Chemicals Inc., Ph-4) was added to a two-necked round-bottom flask and dissolved thoroughly in 300 mL of THF. 15.4 g of NaOH was added to 100 ml of water at 0° C. and then, dissolved therein, until a transparent solution was obtained. A solution of 73 g of para-toluene sulfonyl chloride dissolved in 100 mL of THF was slowly injected at 0° C. Here, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 50 g of the dried product was added in a two-necked round bottom flask and sufficiently stirred in 300 mL of ethanol. Subsequently, 27 g of thiourea was added thereto and dispersed and then, refluxed at 80° C. for 12 hours. Then, an aqueous solution obtained by dissolving 4.4 g of NaOH in 20 ml of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula X was obtained.

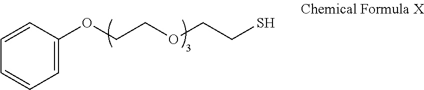

### Comparative Synthesis Example 3

102 g of tetrahydrofurfuryl alcohol and 0.1 g of KOH were placed in a high-pressure reactor and the internal temperature was raised to 80° C. THF-4 was synthesized by slowly adding 176 g of ethylene oxide while controlling the internal pressure. 278 g of THF-4 was added to a two-neck round bottom flask and dissolved sufficiently in 300 mL of THF. At an internal temperature of 0° C., 15.4 g of NaOH and 100 mL of water were added and dissolved sufficiently until a clear solution was obtained. A solution of 73 g of para-toluene sulfonyl chloride dissolved in 100 ml of THF was slowly injected at 0° C. Here, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 50 g of the dried product was added in a two-necked round bottom flask and sufficiently stirred in 300 mL of ethanol. Subsequently, 27 g of thiourea was added thereto and dispersed and then, refluxed at 80° C. for 12 hours. Then, an aqueous solution of 4.4 g of NaOH dissolved in 20 ml of water was injected, and after 5 more hours of reaction, an excessive amount of methylene chloride was added to dilute it. A hydrochloric acid solution was added and extraction, titration, moisture removal, and solvent removal were performed sequentially. By drying in a vacuum oven for 24 hours, a compound represented by Chemical Formula Y was obtained.

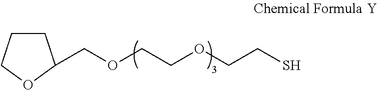

### Comparative Synthesis Example 4

150.22 g of hydroxydicyclopentadiene and 0.1 g of KOH were placed in a high-pressure reactor and the internal temperature was raised to 80° C. HDCP-4 was synthesized by slowly adding 176 g of ethylene oxide while controlling the internal pressure. The compound obtained here was placed in a two-neck round bottom flask, 800 g of cyclohexane, 15 g of sulfuric acid, 120 g of thioglycolic acid, and 0.1 g of methylhydroquinone (MHQ) were added, the temperature was raised to 70° C., and the reaction was carried out for 12 hours while removing the H₂O produced.

When H₂O was no longer produced, it was cooled to room temperature, washed with distilled water twice, neutralized with NaOH aqueous solution once, and washed with distilled water twice sequentially, and then the solvent was removed through reduced pressure drying to finally obtain a compound represented by Chemical Formula Z.

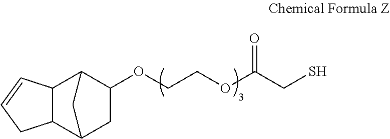

### Second Ligand

### Synthesis Example 2-1

mono-2-(acryloyloxy)ethyl succinate (Sigma Aldrich)

### Synthesis Example 2-2

2-carboxyethyl acrylate (Sigma Aldrich)

### Synthesis Example 2-3

234 g of polyethylene glycol allyl ether (Hannong Chemicals Inc., APEG-4) was added in a two-neck round bottom flask and dissolved sufficiently in 300 mL of THF. At 0° C., 44 g of NaOH and 100 ml of water were added thereto and dissolved sufficiently until a clear solution was obtained. A solution of 210 g of para-toluene sulfonyl chloride dissolved in 300 mL of THF was slowly injected at 0° C. Here, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 389 g of the obtained dried material was placed in a two-necked round bottom flask and stirred thoroughly in 500 mL of ethanol. Then, 152 g of thiourea was added and refluxed at 80° C. for 12 hours. Then, an aqueous solution obtained by dissolving 60 g of NaOH in 200 ml of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula B-3 was obtained.

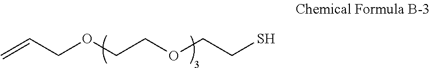

### Synthesis Example 2-4

104 g of ethylene glycol monoacetate, 100 g of succinic anhydride, and 3.0 g of tetrabutylammonium bromide were added to a round flask and reacted at 90° C. for 12 hours to obtain a compound represented by Chemical Formula B-4. After the reaction was completed, it was used immediately without a separate purification process.

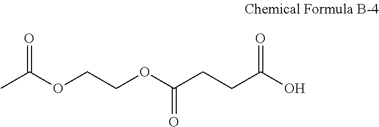

### Preparation of Surface-Modified Quantum Dots

### Preparation Examples 1 to 8 and Comparative Preparation Examples 7 to 22 and Comparative Preparation Examples 29 to 44

A magnetic bar was placed in a 3-neck round bottom flask and a green quantum dot dispersion solution (InP/ZnSe/ZnS, Hansol Chemical; quantum dot solid content (e.g., amount) 26 wt %) was added. The green quantum dots had oleic acid substituted on their surfaces. Subsequently, a respective second ligand was added thereto and then, stirred at 60° C. for 2 hours under a nitrogen atmosphere, and a respective first ligand along with ZnCl₂ was added thereto and then, stirred at 25° C. under a nitrogen atmosphere for 2 hours. When a reaction was completed, the quantum dot reaction solution was cooled to room temperature (23° C.) and then, added to ethanol to catch precipitates. The precipitates were separated from the cyclohexane through centrifugation and sufficiently dried in a vacuum oven for one day to obtain surface-modified green quantum dots.

### Comparative Preparation Examples 1 to 2 and Comparative Preparation Examples 23 to 24

A magnetic bar was placed in a 3-neck round bottom flask and a green quantum dot dispersion solution (InP/ZnSe/ZnS, Hansol Chemical; quantum dot solid content (e.g., amount) 26 wt %) was added. The green quantum dots had oleic acid substituted on their surfaces. Subsequently, a respective first ligand along with ZnCl₂ was added thereto and then, stirred at 25° C. under a nitrogen atmosphere for 2 hours. When a reaction was completed, the quantum dot reaction solution was added to ethanol to catch precipitates. The precipitates were separated from the ethanol through centrifugation and sufficiently dried in a vacuum oven for one day to obtain a surface-modified green quantum dot.

### Comparative Preparation Examples 3 to 6 and Comparative Preparation Examples 25 to 28

A magnetic bar was placed in a 3-neck round bottom flask and a green quantum dot dispersion solution (InP/ZnSe/ZnS, Hansol Chemical; quantum dot solid content (e.g., amount) 26 wt %) was added. The green quantum dots had oleic acid substituted on their surfaces. Subsequently, a respective second ligand was added thereto and then, stirred at 60° C. for 2 hours under a nitrogen atmosphere. When a reaction was completed, the quantum dot reaction solution was cooled to room temperature (23° C.) and then, added to ethanol to catch precipitates. The precipitates were separated from the ethanol through centrifugation and sufficiently dried in a vacuum oven for one day to obtain a surface-modified green quantum dot.

### Preparation of Solvent-free Curable Compositions

Based on the following respective components, curable compositions according to Examples 1 to 8 and Comparative Examples 1 to 22 are prepared.

### (A) Quantum Dot

It is the same as the composition in Tables 1 to 3.

TABLE 1

| | Surface-modifying | Surface-modifying |
|---|---|---|
| Quantum | material | material |
| dot | (first ligand) | (second ligand) |
| A-1 | Synthesis Example 1-1 | Synthesis Example 2-1 |
| A-2 | Synthesis Example 1-1 | Synthesis Example 2-2 |
| A-3 | Synthesis Example 1-1 | Synthesis Example 2-3 |
| A-4 | Synthesis Example 1-1 | Synthesis Example 2-4 |
| A-5 | Synthesis Example 1-2 | Synthesis Example 2-1 |
| A-6 | Synthesis Example 1-2 | Synthesis Example 2-2 |
| A-7 | Synthesis Example 1-2 | Synthesis Example 2-3 |
| A-8 | Synthesis Example 1-2 | Synthesis Example 2-4 |

TABLE 2

| | Surface-modifying | Surface-modifying |
|---|---|---|
| Quantum | material | material |
| dot | (first ligand) | (second ligand) |
| A-9 | Synthesis Example 1-1 | — |
| A-10 | Synthesis Example 1-2 | — |
| A-11 | — | Synthesis Example 2-1 |
| A-12 | — | Synthesis Example 2-2 |
| A-13 | — | Synthesis Example 2-3 |
| A-14 | | Synthesis Example 2-4 |
| A-15 | Comparative Synthesis Example 1 | Synthesis Example 2-1 |
| A-16 | Comparative Synthesis Example 1 | Synthesis Example 2-2 |
| A-17 | Comparative Synthesis Example 1 | Synthesis Example 2-3 |
| A-18 | Comparative Synthesis Example 1 | Synthesis Example 2-4 |

TABLE 3

| | Surface-modifying | Surface-modifying |
|---|---|---|
| Quantum | material | material |
| dot | (first ligand) | (second ligand) |
| A-19 | Comparative Synthesis Example 2 | Synthesis Example 2-1 |
| A-20 | Comparative Synthesis Example 2 | Synthesis Example 2-2 |
| A-21 | Comparative Synthesis Example 2 | Synthesis Example 2-3 |
| A-22 | Comparative Synthesis Example 2 | Synthesis Example 2-4 |
| A-23 | Comparative Synthesis Example 3 | Synthesis Example 2-1 |
| A-24 | Comparative Synthesis Example 3 | Synthesis Example 2-2 |
| A-25 | Comparative Synthesis Example 3 | Synthesis Example 2-3 |
| A-26 | Comparative Synthesis Example 3 | Synthesis Example 2-4 |
| A-27 | Comparative Synthesis Example 4 | Synthesis Example 2-1 |
| A-28 | Comparative Synthesis Example 4 | Synthesis Example 2-2 |
| A-29 | Comparative Synthesis Example 4 | Synthesis Example 2-3 |
| A-30 | Comparative Synthesis Example 4 | Synthesis Example 2-4 |

### (B) Polymerizable Compound

Compound represented by Chemical Formula 3-2 (M200, Miwon Chemical Co., Ltd.)

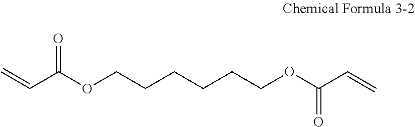 [SMILES: C=CC(=O)OCCCCCCOC(=O)C=C]

### (C) Photopolymerization Initiator

TPO-L (ethyl(2,4,6-trimethylbenzoyl)phenyl phosphinate) (Polynetron Co.)

### (D) Light Diffusing Agent

Titanium dioxide dispersion (rutile type (kind) TiO₂; D50 (180 nm), solid content (e.g., amount) 50 wt %, Iridos Co., Ltd.)

### Examples 1 to 8 and Comparative Examples 1 to 22

For example, the surface-modified green quantum dots and a polymerizable compound were mixed and stirred for 12 hours. A polymerization inhibitor was added thereto and then, stirred for 5 minutes. After adding a photopolymerization initiator thereto, a light diffusing agent was added thereto.

Illustrating Example 1 as an example, 41 g of the surface-modified green quantum dots and 41 g of the compound represented by Chemical Formula 3-2 as the polymerizable compound were mixed and stirred to prepare green quantum dot dispersion, and 11 g of the curable monomer represented by Chemical Formula 3-2 were added thereto and then, stirred for 5 minutes, and subsequently, 3 g of the photopolymerization initiator and 3 g of the light diffusing agent were added thereto and then, stirred, preparing a curable composition (ink))

The specific compositions are shown in Tables 4 to 6 (unit: weight %).

TABLE 4

| | | Ex. 1 | Ex. 2 | Ex. 3 | Ex. 4 | Ex. 5 | Ex. 6 | Ex. 7 | Ex. 8 |
|---|---|---|---|---|---|---|---|---|---|
| Quantum | (A-1) | 41 | — | — | — | — | — | — | — |
| dot | (A-2) | — | 41 | — | — | — | — | — | — |
| | (A-3) | — | — | 41 | — | — | — | — | — |
| | (A-4) | — | — | — | 41 | — | — | — | — |
| | (A-5) | — | — | — | — | 41 | — | — | — |
| | (A-6) | — | — | — | — | — | 41 | — | — |
| | (A-7) | — | — | — | — | — | — | 41 | — |
| | (A-8) | — | — | — | — | — | — | — | 41 |

| | | | | | | | | |
|---|---|---|---|---|---|---|---|---|
| Polymerizable compound | 41 | 41 | 41 | 41 | 41 | 41 | 41 | 41 |
| (for dispersion) | | | | | | | | |
| Polymerizable compound | 11 | 11 | 11 | 11 | 11 | 11 | 11 | 11 |
| Photopolymerization initiator | 3 | 3 | 3 | 3 | 3 | 3 | 3 | 3 |
| Light diffusing agent | 4 | 4 | 4 | 4 | 4 | 4 | 4 | 4 |

unit: wt %

| | | Comp. | Comp. | Comp. | Comp. | Comp. | Comp. | Comp. | Comp. | Comp. | Comp. |
|---|---|---|---|---|---|---|---|---|---|---|---|
| | | Ex. 1 | Ex. 2 | Ex. 3 | Ex 4 | Ex. 5 | Ex. 6 | Ex. 7 | Ex. 8 | Ex. 9 | Ex. 10 |
| Quantum | (A-9) | 41 | — | — | — | — | — | — | — | — | — |
| dot | (A-10) | — | 41 | — | — | — | — | — | — | — | — |
| | (A-11) | — | — | 41 | — | — | — | — | — | — | — |
| | (A-12) | — | — | — | 41 | — | — | — | — | — | — |
| | (A-13) | — | — | — | — | 41 | — | — | — | — | — |
| | (A-14) | — | — | — | — | — | 41 | — | — | — | — |
| | (A-15) | — | — | — | — | — | — | 41 | — | — | — |
| | (A-16) | — | — | — | — | — | — | — | 41 | — | — |
| | (A-17) | — | — | — | — | — | — | — | — | 41 | — |
| | (A-18) | — | — | — | — | — | — | — | — | — | 41 |

| | | | | | | | | | | |
|---|---|---|---|---|---|---|---|---|---|---|
| Polymerizable | 41 | 41 | 41 | 41 | 41 | 41 | 41 | 41 | 41 | 41 |
| compound (for | | | | | | | | | | |
| dispersion) | | | | | | | | | | |
| Polymerizable | 11 | 11 | 11 | 11 | 11 | 11 | 11 | 11 | 11 | 11 |
| compound | | | | | | | | | | |
| Photopolymerization | 3 | 3 | 3 | 3 | 3 | 3 | 3 | 3 | 3 | 3 |
| initiator | | | | | | | | | | |
| Light diffusing | 4 | 4 | 4 | 4 | 4 | 4 | 4 | 4 | 4 | 4 |
| agent | | | | | | | | | | |

TABLE 6
unit: wt %

| | | Comp. | Comp. | Comp. | Comp. | Comp. | Comp. | Comp. | Comp. | Comp. | Comp. | Comp. | Comp. |
|---|---|---|---|---|---|---|---|---|---|---|---|---|---|
| | | Ex. 11 | Ex. 12 | Ex. 13 | Ex 14 | Ex. 15 | Ex. 16 | Ex. 17 | Ex. 18 | Ex. 19 | Ex. 20 | Ex. 21 | Ex. 22 |
| Quantum | (A-19) | 41 | — | — | — | — | — | — | — | — | — | — | — |
| dot | (A-20) | — | 41 | — | — | — | — | — | — | — | — | — | — |
| | (A-21) | — | — | 41 | — | — | — | — | — | — | — | — | — |
| | (A-22) | — | — | — | 41 | — | — | — | — | — | — | — | — |
| | (A-23) | — | — | — | — | 41 | — | — | — | — | — | — | — |
| | (A-24) | — | — | — | — | — | 41 | — | — | — | — | — | — |
| | (A-25) | — | — | — | — | — | — | 41 | — | — | — | — | — |
| | (A-26) | — | — | — | — | — | — | — | 41 | — | — | — | — |
| | (A-27) | — | — | — | — | — | — | — | — | 41 | — | — | — |
| | (A-28) | — | — | — | — | — | — | — | — | — | 41 | — | — |
| | (A-29) | — | — | — | — | — | — | — | — | — | — | 41 | — |
| | (A-30) | — | — | — | — | — | — | — | — | — | — | — | 41 |

| | | | | | | | | | | | | |
|---|---|---|---|---|---|---|---|---|---|---|---|---|
| Polymerizable | 41 | 41 | 41 | 41 | 41 | 41 | 41 | 41 | 41 | 41 | 41 | 41 |
| compound (for | | | | | | | | | | | | |
| dispersion) | | | | | | | | | | | | |
| Polymerizable | 11 | 11 | 11 | 11 | 11 | 11 | 11 | 11 | 11 | 11 | 11 | 11 |
| compound | | | | | | | | | | | | |
| Photopolymerization | 3 | 3 | 3 | 3 | 3 | 3 | 3 | 3 | 3 | 3 | 3 | 3 |
| initiator | | | | | | | | | | | | |
| Light diffusing | 4 | 4 | 4 | 4 | 4 | 4 | 4 | 4 | 4 | 4 | 4 | 4 |
| agent | | | | | | | | | | | | |

### Preparation of Solvent-Based Curable Compositions

Based on the following respective components, curable compositions according to Examples 9 to 16 and Comparative Examples 23 to 44 were prepared.

### (A) Quantum Dot

It is the same as the composition in Tables 1 to 3.

### (B) Polymerizable Compound

Dipentaerythritol hexaacrylate (DPHA, Nippon Kayaku Co., Ltd.)

### (C) Photopolymerization Initiator

Oxime-based initiator (PBG-305 (1,2-propanedione-3-cyclopentyl-1-[4-(phenylthio)phenyl]-2-(O-benzoyl oxime)), Tronyl)

### (D) Light Diffusing Agent

Titanium dioxide dispersion (rutile type (kind) TiO₂; D50 (180 nm), solid content (e.g., amount) 50 wt %, Iridos Co., Ltd.)

### (E) Binder Resin

TA-001 (Tacoma Corporation)

### (F) Solvent

(F-1) Cyclohexyl acetate (Sigma-Aldrich)
(F-2) Propylene glycol monomethylether acetate (PGMEA) (Sigma-Aldrich)

### Examples 9 to 16 and Comparative Examples 23 to 44

The following components were used to prepare each photosensitive resin composition of Examples 9 to 16 and Comparative Examples 23 to 44 having a composition shown in Tables 7 to 9 (unit: wt %).

For example, a photopolymerization initiator was dissolved in a solvent (F-2) and then, sufficiently stirred for 2 hours at room temperature. Subsequently, a polymerizable compound, a binder resin, and a light diffusing agent were added thereto and then, sufficiently stirred for 15 minutes and stirred again for 1 hour at room temperature. Meanwhile a quantum dot and a dispersant were added to a solvent (F-1) and then, stirred at room temperature for 30 minutes to prepare a quantum dot solution. Subsequently, the quantum dot solution was mixed with the other solution in which the photopolymerization initiator and/or the like were dissolved and then, stirred for 30 minutes at room temperature, and the products was three times filtered to remove impurities to prepare a solvent-type (kind) curable composition.

TABLE 7

| | | Ex. 9 | Ex. 10 | Ex. 11 | Ex. 12 | Ex. 13 | Ex. 14 | Ex. 15 | Ex. 16 |
|---|---|---|---|---|---|---|---|---|---|
| Quantum | (A-1) | 9 | — | — | — | — | — | — | — |
| dot | (A-2) | — | 9 | — | — | — | — | — | — |
| | (A-3) | — | — | 9 | — | — | — | — | — |
| | (A-4) | — | — | — | 9 | — | — | — | — |
| | (A-5) | — | — | — | — | 9 | — | — | — |
| | (A-6) | — | — | — | — | — | 9 | — | — |
| | (A-7) | — | — | — | — | — | — | 9 | — |
| | (A-8) | — | — | — | — | — | — | — | 9 |
| Polymerizable compound | | 7 | 7 | 7 | 7 | 7 | 7 | 7 | 7 |
| Photopolymerization initiator | | 7 | 7 | 7 | 7 | 7 | 7 | 7 | 7 |
| Light diffusing agent | | 2 | 2 | 2 | 2 | 2 | 2 | 2 | 2 |
| Binder resin | | 10 | 10 | 10 | 10 | 10 | 10 | 10 | 10 |
| Solvent | (F-1) | 30 | 30 | 30 | 30 | 30 | 30 | 30 | 30 |
| | (F-2) | 35 | 35 | 35 | 35 | 35 | 35 | 35 | 35 |

TABLE 8

| | | Comp. | Comp. | Comp. | Comp. | Comp. | Comp. | Comp. | Comp. | Comp. | Comp. |
|---|---|---|---|---|---|---|---|---|---|---|---|
| | | Ex. 23 | Ex. 24 | Ex. 25 | Ex. 26 | Ex. 27 | Ex. 28 | Ex. 29 | Ex. 30 | Ex. 31 | Ex. 32 |
| Quantum | (A-9) | 9 | — | — | — | — | — | — | — | — | — |
| dot | (A-10) | — | 9 | — | — | — | — | — | — | — | — |
| | (A-11) | — | — | 9 | — | — | — | — | — | — | — |
| | (A-12) | — | — | — | 9 | — | — | — | — | — | — |
| | (A-13) | — | — | — | — | 9 | — | — | — | — | — |
| | (A-14) | — | — | — | — | — | 9 | — | — | — | — |
| | (A-15) | — | — | — | — | — | — | 9 | — | — | — |
| | (A-16) | — | — | — | — | — | — | — | 9 | — | — |
| | (A-17) | — | — | — | — | — | — | — | — | 9 | — |
| | (A-18) | — | — | — | — | — | — | — | — | — | 9 |
| Polymerizable | | 7 | 7 | 7 | 7 | 7 | 7 | 7 | 7 | 7 | 7 |
| compound | | | | | | | | | | | |
| Photopolymerization | | 7 | 7 | 7 | 7 | 7 | 7 | 7 | 7 | 7 | 7 |
| initiator | | | | | | | | | | | |
| Light diffusing | | 2 | 2 | 2 | 2 | 2 | 2 | 2 | 2 | 2 | 2 |
| agent | | | | | | | | | | | |
| Binder resin | | 10 | 10 | 10 | 10 | 10 | 10 | 10 | 10 | 10 | 10 |
| Solvent | (F-1) | 30 | 30 | 30 | 30 | 30 | 30 | 30 | 30 | 30 | 30 |
| | (F-2) | 35 | 35 | 35 | 35 | 35 | 35 | 35 | 35 | 35 | 35 |

TABLE 9

| | | Comp. | Comp. | Comp. | Comp. | Comp. | Comp. | Comp. | Comp. | Comp. | Comp. | Comp. | Comp. |
|---|---|---|---|---|---|---|---|---|---|---|---|---|---|
| | | Ex. 33 | Ex. 34 | Ex. 35 | Ex. 36 | Ex. 37 | Ex. 38 | Ex. 39 | Ex. 40 | Ex. 41 | Ex. 42 | Ex. 43 | Ex. 44 |
| Quantum | (A-19) | 9 | — | — | — | — | — | — | — | — | — | — | — |
| dot | (A-20) | — | 9 | — | — | — | — | — | — | — | — | — | — |
| | (A-21) | — | — | 9 | — | — | — | — | — | — | — | — | — |
| | (A-22) | — | — | — | 9 | — | — | — | — | — | — | — | — |
| | (A-23) | — | — | — | — | 9 | — | — | — | — | — | — | — |
| | (A-24) | — | — | — | — | — | 9 | — | — | — | — | — | — |
| | (A-25) | — | — | — | — | — | — | 9 | — | — | — | — | — |
| | (A-26) | — | — | — | — | — | — | — | 9 | — | — | — | — |
| | (A-27) | — | — | — | — | — | — | — | — | 9 | — | — | — |
| | (A-28) | — | — | — | — | — | — | — | — | — | 9 | — | — |
| | (A-29) | — | — | — | — | — | — | — | — | — | — | 9 | — |
| | (A-30) | — | — | — | — | — | — | — | — | — | — | — | 9 |
| Polymerizable | | 7 | 7 | 7 | 7 | 7 | 7 | 7 | 7 | 7 | 7 | 7 | 7 |
| compound | | | | | | | | | | | | | |
| Photopolymerization | | 7 | 7 | 7 | 7 | 7 | 7 | 7 | 7 | 7 | 7 | 7 | 7 |
| initiator | | | | | | | | | | | | | |
| Light diffusing | | 2 | 2 | 2 | 2 | 2 | 2 | 2 | 2 | 2 | 2 | 2 | 2 |
| agent | | | | | | | | | | | | | |
| Binder resin | | 10 | 10 | 10 | 10 | 10 | 10 | 10 | 10 | 10 | 10 | 10 | 10 |
| Solvent | (F-1) | 30 | 30 | 30 | 30 | 30 | 30 | 30 | 30 | 30 | 30 | 30 | 30 |
| | (F-2) | 35 | 35 | 35 | 35 | 35 | 35 | 35 | 35 | 35 | 35 | 35 | 35 |

### Evaluation: Evaluation of Light Resistance Reliability of Curable Compositions

The light resistance reliability of each of the curable compositions according to Examples 1 to 16 and Comparative Examples 1 to 44 was evaluated, and the results are shown in Tables 10 to 12.

### Method for Evaluating Light Resistance Reliability

The prepared curable composition was manufactured into a 2 cm×2 cm single film specimen and then, measured with respect to light efficiency over time under a light source condition of blue 100,000 nit by using a blue LED planar light source.

The single film specimen was measured with respect to light efficiency and luminance over time by using an integrating sphere equipment (QE-2100, Otsuka Electronics Co., Ltd.) and an in-line luminance meter (M7000, McScience Inc.).

Based on 100% of an initial measurement, T90 (time taken until 100% of the initial light efficiency measurement drops to 90%) was compared and evaluated.

TABLE 10

| | T90 (hr) |
|---|---|
| Example 1 | 1000 |
| Example 2 | 1000 |
| Example 3 | 1000 |
| Example 4 | 210 |
| Example 5 | 1000 |
| Example 6 | 1000 |
| Example 7 | 1000 |
| Example 8 | 200 |
| Example 9 | 500 |
| Example 10 | 500 |
| Example 11 | 500 |
| Example 12 | 150 |
| Example 13 | 500 |
| Example 14 | 500 |
| Example 15 | 500 |
| Example 16 | 146 |

TABLE 11

| | T90 (hr) |
|---|---|
| Comparative Example 1 | 230 |
| Comparative Example 2 | 220 |
| Comparative Example 3 | 150 |
| Comparative Example 4 | 130 |
| Comparative Example 5 | 140 |
| Comparative Example 6 | 100 |
| Comparative Example 7 | 140 |
| Comparative Example 8 | 125 |
| Comparative Example 9 | 130 |
| Comparative Example 10 | 90 |
| Comparative Example 11 | 370 |
| Comparative Example 12 | 365 |
| Comparative Example 13 | 370 |
| Comparative Example 14 | 120 |
| Comparative Example 15 | 510 |
| Comparative Example 16 | 500 |
| Comparative Example 17 | 500 |
| Comparative Example 18 | 140 |
| Comparative Example 19 | 480 |
| Comparative Example 20 | 470 |
| Comparative Example 21 | 475 |
| Comparative Example 22 | 135 |

TABLE 12

| | T90 (hr) |
|---|---|
| Comparative Example 23 | 160 |
| Comparative Example 24 | 150 |
| Comparative Example 25 | 104 |
| Comparative Example 26 | 90 |
| Comparative Example 27 | 97 |
| Comparative Example 28 | 70 |
| Comparative Example 29 | 97 |
| Comparative Example 30 | 84 |
| Comparative Example 31 | 90 |
| Comparative Example 32 | 65 |
| Comparative Example 33 | 255 |
| Comparative Example 34 | 220 |
| Comparative Example 35 | 240 |
| Comparative Example 36 | 83 |
| Comparative Example 37 | 355 |
| Comparative Example 38 | 310 |
| Comparative Example 39 | 330 |
| Comparative Example 40 | 100 |
| Comparative Example 41 | 335 |
| Comparative Example 42 | 290 |
| Comparative Example 43 | 310 |
| Comparative Example 44 | 95 |

From Tables 10 to 12, it is confirmed that the curable composition according to one or more embodiments significantly improves light resistance reliability, regardless of whether a solvent is included.

In present disclosure, the wording “component-free” refers to that the “component” not being added, selected, or utilized as a component in the composition/element, but, in some embodiments, the “component” of less than a suitable amount may still be included due to other impurities and/or external factors.

In the present disclosure, the term “comprise(s)/comprising”. “include(s)/including”, or “have (has)/having” are intended to designate that the performed characteristics, numbers, step, constituted elements, or a combination thereof is present, but it should be understood that the possibility of presence or addition of one or more other characteristics, numbers, steps, constituted element, or a combination are not to be precluded in advance. Additionally, the terms “comprise(s)/comprising,” “include(s)/including,” “has (have)/having”, or other similar terms include or support the terms “consisting of” and “consisting essentially of,” indicating the presence of stated features, numbers, steps, operations, elements, parts, and/or components, without or essentially without the presence of other features, numbers, steps, operations, elements, parts, components, and/or groups thereof.

As used herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure.” Expressions such as “at least one of,” “one of,” and “selected from,” when preceding a list of elements, modify the entire list of elements and do not modify the individual elements of the list. For example, “at least one of a, b, or c,” “at least one of a, b, and/or c,” “at least one selected from a, b, and c,” “at least one selected from among a to c,” etc. may indicate only a, only b, only c, both (e.g., simultaneously) a and b, both (e.g., simultaneously) a and c, both (e.g., simultaneously) b and c, all of a, b, and c, or variations thereof. Further, the “/” utilized herein may be interpreted as “and” or as “or” depending on the situation.

In the context of the present application and unless otherwise defined, the terms “use,” “using,” and “used” may be considered synonymous with the terms “utilize,” “utilizing,” and “utilized,” respectively.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The composition manufacturing apparatus, the film-manufacturing apparatus such as coating apparatus, photolithography apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

While this disclosure has been described in connection with what is presently considered to be practical example embodiments, it is to be understood that the present disclosure is not limited to the disclosed embodiments, but, on the contrary, is intended to cover one or more suitable modifications and equivalent arrangements included within the spirit and scope of the appended claims and equivalents thereof. Therefore, the aforementioned embodiments should be understood to be examples but not limiting the disclosure in any way.

What is claimed is:

1. A curable composition, comprising
a quantum dot comprising a first functional group represented by Chemical Formula 1 and a second functional group having a different structure from the first functional group; and
a polymerizable compound: 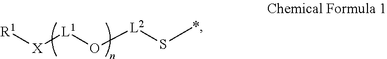
wherein, in Chemical Formula 1,
X is sulfur or oxygen,
R¹ is a monovalent functional group comprising a reactive group and a C3 to C20 cycloalkane ring,
L¹ and L² are each independently a substituted or unsubstituted C1 to C20 alkylene group, and
n is an integer between 2 and 10.

2. The curable composition as claimed in claim 1, wherein
the reactive group comprises a carbon-carbon double bond, an epoxy group, or a combination thereof.

3. The curable composition as claimed in claim 1, wherein
R¹ is represented by any one selected from among Chemical Formulas R-1 to R-3: 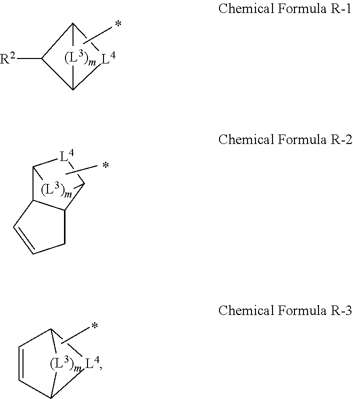
in Chemical Formulas R-1 to R-3,
R² being a substituted or unsubstituted vinyl group, a substituted or unsubstituted epoxy group, or a C1 to C20 alkyl group substituted with an epoxy group and/or a vinyl group,
L³ and L⁴ being each independently a substituted or unsubstituted C1 to C10 alkylene group, and
m being an integer of 0 or 1.

4. The curable composition as claimed in claim 1, wherein
the first functional group represented by Chemical Formula 1 is represented by any one selected from among Chemical Formula 1-1 to Chemical Formula 1-4: 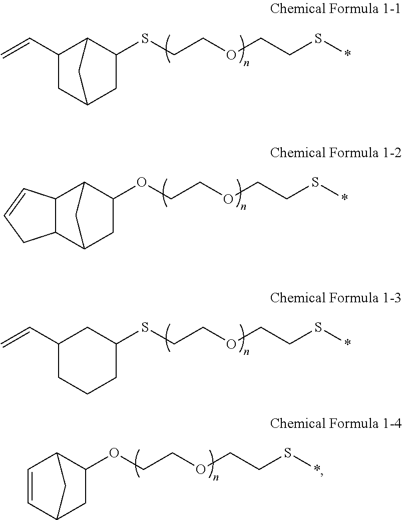
in Chemical Formula 1-1 to Chemical Formula 1-4,
n being an integer between 2 and 10.

5. The curable composition as claimed in claim 1, wherein
the first functional group represented by Chemical Formula 1 is derived from a compound represented by Chemical Formula 11: 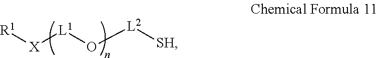
in Chemical Formula 11,
X being sulfur or oxygen,
R¹ being a monovalent functional group comprising a reactive group and a C3 to C20 cycloalkane ring,
L¹ and L² being each independently a substituted or unsubstituted C1 to C20 alkylene group, and
n being an integer between 2 and 10.

6. The curable composition as claimed in claim 1, wherein
the second functional group is represented by Chemical Formula 2 or Chemical Formula 3: 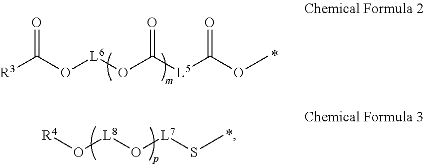
in Chemical Formula 2 and Chemical Formula 3,
R³ and R⁴ being each independently a substituted or unsubstituted vinyl group, a substituted or unsubstituted epoxy group, or a C1 to C20 alkyl group substituted with an epoxy group and/or a vinyl group,
L⁵ to L⁸ being each independently a substituted or unsubstituted C1 to C20 alkylene group, and
m and p being each independently an integer from 0 to 10.

7. The curable composition as claimed in claim 6, wherein
the second functional group represented by Chemical Formula 2 is represented by Chemical Formula 2-1 or Chemical Formula 2-2: 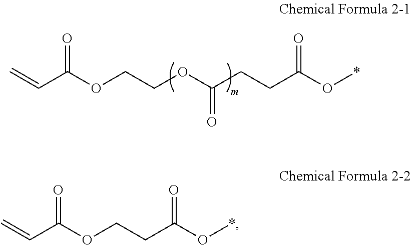
in Chemical Formula 2-1,
m being an integer from 1 to 10.

8. The curable composition as claimed in claim 6, wherein
the second functional group represented by Chemical Formula 3 is represented by Chemical Formula 3-1: 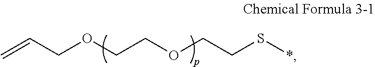
in Chemical Formula 3-1,
p being an integer from 0 to 10.

9. The curable composition as claimed in claim 1, wherein
the second functional group is derived from a compound represented by Chemical Formula 12 or Chemical Formula 13: 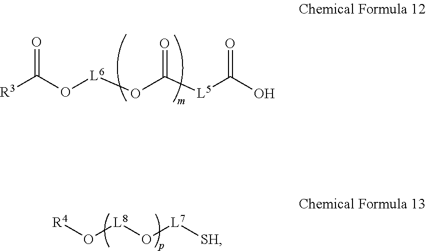
in Chemical Formula 12 and Chemical Formula 13,
R³ and R⁴ being each independently a substituted or unsubstituted vinyl group, a substituted or unsubstituted epoxy group, or a C1 to C20 alkyl group substituted with an epoxy group and/or a vinyl group,
L⁵ to L⁸ being each independently a substituted or unsubstituted C1 to C20 alkylene group, and
m and p being each independently an integer from 0 to 10.

10. The curable composition as claimed in claim 1, wherein
the curable composition is a solvent-free curable composition.

11. The curable composition as claimed in claim 10, wherein
the solvent-free curable composition comprises:
about 5 wt % to about 60 wt % of the quantum dot; and
about 40 wt % to about 95 wt % of the polymerizable compound,
based on a total amount of the solvent-free curable composition.

12. The curable composition as claimed in claim 1, wherein
the curable composition further comprises a polymerization initiator, a light diffusing agent, a polymerization inhibitor, or a combination thereof.

13. The curable composition as claimed in claim 12, wherein
the light diffusing agent comprises barium sulfate, calcium carbonate, titanium dioxide, zirconia, or a combination thereof.

14. The curable composition as claimed in claim 1, wherein
the quantum dot comprises a cadmium-free light emitting material.

15. The curable composition as claimed in claim 14, wherein
the quantum dot has a core/shell structure of InP/ZnS or a core/first shell/second shell structure of InP/ZnSe/ZnS.

16. The curable composition as claimed in claim 1, wherein
the quantum dot comprises:
a core comprising Ag, In, Ga, and S; and
a shell comprising at least two selected from among Ag, Ga, Zn, and S.

17. The curable composition as claimed in claim 1, wherein
the curable composition further comprises a solvent.

18. The curable composition as claimed in claim 17, wherein
the curable composition comprises:
about 1 wt % to about 40 wt % of the quantum dot;
about 1 wt % to about 20 wt % of the polymerizable compound; and
about 40 wt % to about 80 wt % of the solvent,
based on a total weight of the curable composition.

19. A cured layer produced utilizing the curable composition as claimed in claim 1.

20. A display device comprising the cured layer as claimed in claim 19.
